(19) United States
(12) Patent Application Publication
(10) Pub. No.: US 2026/0058610 A1
(43) Pub. Date: Feb. 26, 2026

(54) TRACKING AMPLIFIER FOR INDUCTIVE LOADS

(71) Applicant: Robert Bosch GmbH, Stuttgart (DE)

(72) Inventors: Raik Fiedler, Peitz (DE); Hermann Schenk, Dresden (DE)

(21) Appl. No.: 18/997,530

(22) PCT Filed: Jul. 18, 2023
(86) PCT No.: PCT/EP2023/069889

§ 371 Date: Jan. 22, 2025

(30) Foreign Application Priority Data
Jul. 22, 2022 (DE) 10 2022 118 419.6
Jul. 22, 2022 (DE) 10 2022 118 422.6
Jul. 22, 2022 (DE) 10 2022 118 423.4
Jul. 22, 2022 (DE) 10 2022 118 432.3

(51) Int. Cl. H03F 1/26; H03F 3/45

(52) U.S. Cl. CPC H03F 1/26; H03F 3/45475; H03F 2203/45692

(57) ABSTRACT

The invention generally relates to amplifier circuits for coupling and/or driving an inductive load with a time-continuous current. Example embodiments of the amplifier circuits disclosed herein may for example be used for driving, for example, electrodynamic converters that generate acoustic pressure, which may be in form of a System-on-Chip (SoC) or a System-in-Package (SiP).

### TECHNICAL FIELD

Embodiments of the invention generally relate to amplifier circuits for coupling and/or driving an inductive load. Example embodiments of the amplifier circuits disclosed herein may for example be used for driving, for example, electrodynamic converters that generate acoustic pressure, which may be in form of a System-on-Chip (SoC) or a System-in-Package (SiP).

### BACKGROUND

Amplifier circuits are commonly divided into two categories. One category of amplifiers are voltage amplifiers to convert an input signal with a small input amplitude into an output signal with a larger voltage amplitude. This type of amplifiers is commonly referred to as a small-signal amplifier in literature. When for example used with an exemplary sensor element, the voltage amplifiers'small output amplitudes can be processed for the next function block in the signal processing chain. The other category of amplifiers are current amplifiers that focus and provide on higher output currents. Alternatively, current amplifiers are also referred to as power amplifiers. When used in conjunction with acoustic pressure-generating (electrodynamic) devices, power amplifier may for example be used to provide the control signals for actuators of the acoustic pressure-generating (electrodynamic) devices. Of course, mixed forms of these two categories can also be found in technical applications, also regarding the processing of time and value-continuous (=analog) or time and value-discrete (=digital) signals.

Due to the technical importance, the following description puts focus on amplification of analog voltages and currents. In principle, an electrical amplifier is an indispensable component in today's technology. Regardless of the implementation chosen, the power required for amplification is commonly supplied by a power supply device or element, e.g. a battery. Depending on how this power is processed, amplifiers are commonly divided in different classes.

The amplifier topologies most commonly used today are referred to as AB-, D-, G- or H-class amplifiers.

Class AB amplifiers typically have an output stage formed by an n-type and p-type transistor which are driven by an operational amplifier input stage. Both transistors are driven continuously, i.e. not on an on-off scheme (as for example in Class D amplifiers, see below). The overall circuit is usually designed as a non-inverting amplifier. Since the time-continuous input signal is available at the output of the class AB amplifier with the corresponding amplification factor, no additional filter stage is necessary in the feedback path. However, since the output stage conducts current continuously, the power consumption of class AB amplifiers is often considered problematic, especially at higher output voltages.

The output stage of the class D amplifier is usually controlled via pulse width modulation (PWM), which reduces its power loss to the currents at the moment of switching. To generate the PWM signal, the analog input signal to be amplified is commonly sampled with a sawtooth voltage using a comparator. Following the output stage, a low-pass filter with a sufficiently steep edge is commonly required to filter out the analog fundamental component on the input side from the high-frequency digital signal.

A further improvement of class D amplifiers is a class G amplifier. Class G amplifiers typically have fixed and switchable supply voltage levels for its output-side push-pull stage. This switching of the supply voltage levels can be implemented dynamically or by an external control signal and leads to better energy efficiency compared to class D amplifiers, since the energy that needs to be filtered by the output filter can be reduced for smaller output amplitudes.

The class H amplifiers try to minimize power loss of the class AB amplifiers by adjusting the supply voltage of the output stage. The adjustment of the supply power rails is often realized using an external feed with a step-up and step-down converter, which requires a coil that can typically not be integrated into an integrated circuit (IC) due to its size. In addition to the space required for external components in an IC implementation, the high complexity of class H amplifiers is also a disadvantage. With suitable designs, however, class H amplifiers may not require an output filter for signal filtering on the output side.

Important properties for the design and realization of amplifier circuits can be derived from the technical requirements for electronic amplifiers. The first thing to mention here is the linearity, which translates directly into the freedom from distortion of the amplified output signal. Accordingly, an ideal amplifier would cause no deviations from the input signal or, depending on the gain factor, the multiple of the input signal. Furthermore, the amplifier's efficiency is commonly also of decisive importance when choosing an amplifier design in order to use as much of the supplied power as possible for the actual useful output signal. Conversely, a real amplifier will consume additional energy in its output stage or through downstream filter stages. From a system perspective, the complexity of the amplifiers also plays an important role. Complexity cannot be summarized in a single key figure. However, important factors for the complexity of an amplifier design are typically the number of transistors, the area on the die, the use of external components (such as coils, capacitors and resistors) or additional functional blocks (such as voltage converters and active filters). Furthermore, the load on the output side defines the required output voltages and output currents and their frequency-dependent behavior in the case of reactive elements such as coils and capacitors.

According to the criteria described, the amplifier classes presented in the prior art have different strengths and weaknesses. In terms of energy efficiency, the power and filter stages at the output side are usually decisive. The class H amplifier is generally considered the measure of all things, as it combines the advantageous push-pull stage of a class D amplifier with a filter-free design like the class AB amplifier. The push-pull stage allows power to flow only from the supply source to the load or from the load to ground, avoiding unwanted cross currents when the load is to be powered. In connection with a variably modulated supply source, the desired voltages and currents with low ripple can be generated at the load without a filter. In general, class H amplifier only make as much power available at the output as the system consisting of the amplifier and the load requires at the corresponding switching moment. The amount of power and thus the output signal follows the desired and amplified target signal.

FIG. 1 shows an example tracking amplifier circuit 100 adapted to driving capacitive loads 110. The functioning of the entire circuit corresponds to the principle of a control loop. A time-continuous input signal 102 to be amplified is provided to the non-inverting input terminal A of the comparator 104. The comparator 104 further receives a feedback signal at is inverting input terminal B and compares the signal 102 and the feedback signal to provide the result of the comparison at the output terminal C of the comparator 104. The output signal of the comparator 104 drives the push-pull stage 108 of the amplifier 100. In the example shown, a simple inverter stage with the two transistors 112 and 114 implements the push-pull stage 108 to provide the amplified output signal of the amplifier 100 at the output terminal D. The output signal is applied to the capacitive load 110. The time-continuous output signal at the output terminal D is fed back to input terminal B of the comparator 104 via an adjustable voltage divider 116 that exemplarily consists of two resistors.

Depending on the two input signals at the terminals A and B of the comparator 104, a digital signal with a high or low level is generated at the output terminal C of the comparator 104. This resulting digital signal may be first be buffered and/or amplified in the buffer or inverter stage 106 and is in turn used to control the transistors 112, 114 of the push-pull inverter stage 108.

A digital pulse width modulated (PWM) signal is thus produced at the output terminal D of the amplifier 100. However, due to the capacitive load 110, this PWM output signal is integrated. Depending on the drive strength of the push-pull inverter stage 108 and the load 110's capacitance, the rate of change of the output signal at the terminal D of the push-pull inverter stage 108 (which is also the output terminal of the amplifier 100) is thus limited so that the feedback path 118 may be implemented using the voltage divider 116 without any additional feedback filter in order to form a stable and continuous control loop. As a result, the output signal is smoothed without external modulation of the power supply source 120 and without additional filter stages in the feedback path 118. The output signal at the output terminal D and its divided equivalent at input terminal B of the comparator 104 will thus follow the input signal at terminal A.

The limitation of the tracking amplifier 100 in FIG. 1 is the need for a load 110 having sufficient capacitance that integrates the output voltage at the output node D to enable the desired control loop. In principle, the tracking amplifier 100 in FIG. 1 could also be operable with other loads, but if the load has no capacitive component or the capacitance of the load is too low, no time-continuous voltage would be present at the load. If a purely resistive load was used, only digital amplification would be possible, as the PWM signal at the output terminal D of the push-pull inverter stage 108 would be fed back to the inverting terminal B of the comparator 104 without any delay or integration so that the control loop would immediately adapt the output signal. If the amplifier 100 was connected to an inductive load, a reactive element would still be present, but the amplifier 100 would still not achieve the desired result, i.e. the amplifier 100 would not output a time-continuous output current. The reason for this is the opposite physical behavior of the current and voltage of a capacitive load 110 compared to an inductive load. While the electrical field of a capacitance is controlled by the applied voltage, the magnetic field of a coil is determined by the current flowing through it.

Within this context, there is a need to improve the design of the exemplary tracking amplifier 100 shown in FIG. 1 so that the amplifier circuit can drive an inductive load with a time-continuous current and ensures low power consumption and efficient amplification at the same time.

### BRIEF SUMMARY OF THE INVENTION

This Brief Summary is provided to introduce a selection of concepts in a simplified form that are further described below in the Detailed Description. This Summary is not intended to identify key features or essential features of the claimed subject matter.

Aspects of the invention bring together as many of the requirements on the design of an amplifier circuit described herein above in a new amplifier design that allows driving inductive loads and without the need of a complex output filter. One design aspect is to produce a time-continuous output current at the output terminal of the amplifier circuit and convert this time-continuous output current into a time-continuous output voltage that can be fed back as a feedback signal to a comparator to implement the control loop. In general, the amplifier circuit may for example produce a PWM voltage signal at the output, which causes a time-continuous output current to flow towards the load. The conversion of the time-continuous current into a time-continuous voltage can be implemented using a feedback network that is in between the output node of the amplifier circuit and the input node of the comparator. The feedback network can be arranged in parallel to the load branch or in series to the load branch, as will become more apparent from the following examples. Furthermore, the amplifier design according to the different embodiments of the invention may use different voltage domains for the comparator, a buffer stage (if present) and the amplification stage.

Embodiments of the invention provide different exemplary implementations of an amplifier circuit for coupling to an inductive load. In those different exemplary implementations, the amplifier circuit comprises an amplification stage. The amplification stage may comprise a comparator. The comparator has a non-inverting input terminal and an inverting input terminal to receive a signal to be amplified and a feedback signal. The comparator is to produce and output at its output terminal a comparator output signal that is obtained by comparing the signal to be amplified and the feedback signal and is indicative of the result of the comparison. The amplification stage may further comprise an inverter stage to generate a pulse-width modulated signal in response to the comparator output signal and to output the pulse-width modulated signal as a time-continuous current signal at an output terminal of the inverter stage. The output terminal of the inverter stage may be also the output terminal of the amplifier circuit.

The amplifier circuit further comprises a feedback stage. In some embodiments, the feedback stage may comprise a feedback filter that is to be coupled in parallel to the inductive load and that is coupled directly to the output terminal of the inverter stage to receive and convert the time-continuous current signal into a time-continuous voltage signal. “Coupled directly” means here that the feedback filter is coupled to the same output potential at the output terminal of the inverter stage as the inductive load. The feedback stage may further include a voltage divider that receives the time-continuous voltage signal at its input and that is coupled to the reference potential at its output. The voltage divider may be configured to provide the time-continuous voltage signal at a reduced voltage level as the feedback signal to the comparator.

In a further exemplary embodiment, the signal to be amplified by the amplifier circuit is received at the non-inverting input terminal of the comparator and the feedback signal is received at the inverting input terminal of the comparator.

According to a further embodiment, the feedback filter is a low-pass filter. In an exemplary implementation, the impedance of the feedback filter is higher than the impedance of the inductive load to minimize the power flowing into the feedback filter.

In another embodiment, the voltage divider may be formed by a first resistor and a second resistor coupled in series. The first resistor has one terminal coupled to an output of the feedback filter to receive a time-continuous voltage signal and another terminal coupled to the one of the input terminals of the comparator to provide the feedback signal. The second resistor has one terminal coupled to the other terminal of the first resistor and another terminal coupled to the reference potential.

In an alternative embodiment, the voltage divider comprises a first capacitor and a second capacitor coupled in series. In this embodiment, the first capacitor has one terminal coupled to an output of the feedback filter to receive a time-continuous voltage signal and another terminal coupled to the one of the input terminals of the comparator to provide the feedback signal; and the second capacitor has one terminal coupled to the other terminal of the first capacitor and another terminal coupled to the reference potential.

As noted above, the amplifier circuit further comprises a feedback stage. In some embodiments, the feedback stage may comprise an inductor and a resistor coupled parallel. The inductor and resistor may form a feedback network. The inductor magnetically couples to the inductive load to receive the time-continuous current signal through the inductive load. The magnetic coupling to the inductive load may induce a current signal in the feedback network that is received from the inductance of the load. The induced current signal may be a mirrored current the waveform of which mirrors the time-continuous current signal flowing through the inductive load. The resistor converts the received time-continuous current signal into a time-continuous voltage signal. The feedback stage may further include a voltage divider that receives the time-continuous voltage signal at its input and that is coupled to the reference potential at its output. The voltage divider may be configured to provide the time-continuous voltage signal at a reduced voltage level as the feedback signal to the comparator.

In a further embodiment, the inductor and the resistor of the feedback stage are connected in parallel to the inductive load.

In another embodiment, one terminal of each of the resistor and the inductor of the feedback stage are connected to the same reference potential and one terminal of the inductive load.

In a further exemplary embodiment, the signal to be amplified by the amplifier circuit is received at non-inverting input terminal of the comparator and the feedback signal is received at the inverting input terminal of the comparator.

In another embodiment, the voltage divider may be formed by a first resistor and a second resistor coupled in series. The first resistor has one terminal coupled to the resistor of the feedback stage to receive the time-continuous voltage signal and another terminal coupled to the one of the input terminals of the comparator to provide the feedback signal. The second resistor has one terminal coupled to the other terminal of the first resistor and another terminal coupled to the reference potential.

In an alternative embodiment, the voltage divider comprises a first capacitor and a second capacitor coupled in series. In this embodiment, the first capacitor has one terminal coupled to an output of the feedback stage to receive a time-continuous voltage signal and another terminal coupled to the one of the input terminals of the comparator to provide the feedback signal; and the second capacitor has one terminal coupled to the other terminal of the first capacitor and another terminal coupled to the reference potential.

As noted above, the amplifier circuit further comprises a feedback stage. In some embodiments, the feedback stage comprises a resistor coupled in series with the inductive load, wherein the resistor is to convert the time-continuous current signal flowing through the inductive load into a time-continuous voltage signal. The resistor converts the received time-continuous current signal into a time-continuous voltage signal. The feedback stage may further include a voltage divider that receives the time-continuous voltage signal at its input and that is coupled to the reference potential at its output. The voltage divider may be configured to provide the time-continuous voltage signal at a reduced voltage level as the feedback signal to the comparator.

In a further embodiment, the resistor of the feedback stage has a first terminal connected to the inductive load and another second terminal connected to a reference potential, and the input of the voltage divider is connected to the first terminal. In an example implementation, the inductive load and the resistor of the feedback stage form a second voltage divider.

In another example implementation of this embodiment, a second inductive load is connected in series with the inductive load and in parallel with the resistor of the feedback stage. In other words, in this implementation example, the two inductive loads may also be referred to as individual inductive load components of a common inductive load, where the resistor is connected in parallel to one of those load components, i.e. the second inductive load component. The two load components may have same inductance and/or same impedance. The first and second inductive loads are connected in series, like a voltage divider, and the resistor is connected to the “center tap” between the two inductive load components.

In a further exemplary embodiment, the signal to be amplified by the amplifier circuit is received at non-inverting input terminal of the comparator and the feedback signal is received at the inverting input terminal of the comparator.

In an example embodiment, the signal to be amplified has a voltage level relative to the reference potential.

In another embodiment, the voltage divider may be formed by a first resistor and a second resistor coupled in series. The first resistor has one terminal coupled to the first terminal of the resistor of the feedback stage to receive the time-continuous voltage signal and another terminal coupled to the one of the input terminals of the comparator to provide the feedback signal. The second resistor has one terminal coupled to the other terminal of the first resistor and another terminal coupled to the reference potential.

In an alternative embodiment, the voltage divider comprises a first capacitor and a second capacitor coupled in series. In this embodiment, the first capacitor has one terminal coupled to the first terminal of the resistor of the feedback stage to receive a time-continuous voltage signal and another terminal coupled to the one of the input terminals of the comparator to provide the feedback signal; and the second capacitor has one terminal coupled to the other terminal of the first capacitor and another terminal coupled to the reference potential.

As noted above, the amplifier circuit further comprises a feedback stage. In some embodiments, the feedback stage may comprise a current mirror having a first path through which the time-continuous current signal is to flow and a second path. The current mirror is configured to cause a mirrored time-continuous current signal to flow through the second path of the current mirror. The mirrored time-continuous current signal corresponding to the time-continuous current signal flowing through the first path. The feedback stage may further comprise a resistor having one terminal connected to the second path of the current mirror, and another terminal connected either to the output terminal of the amplifier circuit or a reference potential. The resistor is configured to convert the mirrored time-continuous current signal flowing through the second path of the current mirror into a time-continuous voltage signal. The feedback stage may further include a voltage divider that receives the time-continuous voltage signal at its input and that is coupled to the reference potential at its output. The voltage divider may be configured to provide the time-continuous voltage signal at a reduced voltage level as the feedback signal to the comparator.

In one embodiment, the first terminal of the resistor of the feedback stage is connected to the output terminal of the inverter stage and the second terminal of the resistor is connected to the input terminal of the voltage divider and the second path of the current mirror. The second path of the current mirror is connected between the second terminal of the resistor and a reference potential, and the first path of the current mirror is connected between the inductive load and said reference potential. In this embodiment, the current mirror may be implemented using n-type transistors. In an alternative embodiment, the first terminal of the resistor of the feedback stage is connected to a reference potential and the second terminal of the resistor is connected to the input terminal of the voltage divider and the second path of the current mirror. The second path of the current mirror is connected between the output terminal of the inverter stage and the second terminal of the resistor, and the first path of the current mirror is connected between the output terminal of the inverter stage and the inductive load. In this embodiment, the current mirror may be implemented using p-type transistors.

In further embodiments, the mirrored time-continuous current signal flowing through the second path of the current mirror may be proportional and smaller than the time-continuous current signal flowing through the first path of the current mirror. For example, the mirrored time-continuous current signal flowing through the second path of the current mirror may be a factor of 1/N smaller than the time-continuous current signal to flowing through the first path of the current mirror. In addition, or alternatively, the resistance of the resistor of the feedback path may be N times larger than the resistances of the inductive load.

According to further embodiments, the first path of the current mirror comprises a first number of first transistors connected in parallel with each other. The first transistors connected in parallel receive the time-continuous current signal flowing through the inductive load at their gate terminal. The first path of the current mirror may further include the first number of second transistors connected in parallel with each other and connected in series with to the first transistors, wherein the gate terminals of the second transistors receive the current flowing through the first transistors. In this example, the number of first transistors and second transistors is selected to be the same for example purposes only; it is possible that different numbers of first and second transistors are used. Likewise, the second path of the current mirror comprises a second number of third transistors connected in parallel with each other and having their gate terminals coupled to the gate terminals of the first transistors, and the second number of fourth transistors connected in parallel with each other and connected in series with to the third transistors, wherein the gate terminals of the fourth transistors are coupled to the gate terminals of the second transistors. In this example, the number of third transistors and fourth transistors is selected to be the same for example purposes only; it is possible that different numbers of third and fourth transistors are used. In an example implementation, the first number is an integer multiple (e.g. N times) of the second number.

In a further exemplary embodiment, the signal to be amplified by the amplifier circuit is received at non-inverting input terminal of the comparator and the feedback signal is received at the inverting input terminal of the comparator.

In another embodiment, the voltage divider may be formed by a first resistor and a second resistor coupled in series. The first resistor has one terminal coupled to an output of the feedback filter to receive a time-continuous voltage signal and another terminal coupled to the one of the input terminals of the comparator to provide the feedback signal. The second resistor has one terminal coupled to the other terminal of the first resistor and another terminal coupled to the reference potential.

In an alternative embodiment, the voltage divider comprises a first capacitor and a second capacitor coupled in series. In this embodiment, the first capacitor has one terminal coupled to an output of the feedback filter to receive a time-continuous voltage signal and another terminal coupled to the one of the input terminals of the comparator to provide the feedback signal; and the second capacitor has one terminal coupled to the other terminal of the first capacitor and another terminal coupled to the reference potential.

The following embodiments pertain to all example implementations of the feedback stage of the amplifier circuits discussed herein. In a further embodiment of the invention the signal to be amplified has a voltage level relative to the reference potential.

According to a further embodiment, the amplification stage further comprises one or more buffer circuits which are connected in series between the output terminal of the comparator and an input terminal of the inverter stage. In the embodiments shown herein, the input terminal of the inverter stage may connect to the gate terminals of the active elements (transistors) in the inverter stage.

In an example implementation of this embodiment, the one or more buffer circuits are configured to perform level shifting of the comparator output signal and to provide the level shifted comparator output signal to the input terminal of the inverter stage. Further, the one or more buffer circuits could be configured to amplify the drive strength of the signal applied to the input terminal of the inverter stage.

In another embodiment, the inverter stage comprises at least one pair of push-pull transistors connected in series and forming a push-pull configuration. In an example, the drain terminals of the push-pull transistors may be connected to each other and provide the output terminal of the inverter stage. A first push-pull transistor of the pair of push-pull transistors may be a p-type transistor and the other second push-pull transistor of the pair of push-pull transistors may be a n-type transistor.

In one example implementation of this embodiment, a first push-pull transistor of the pair of push-pull transistors may be connected to a first reference potential and another second push-pull transistor of the pair of push-pull transistors is connected to a second reference potential, which is different from the first reference potential. The amplifier circuit may further comprise a first bias control circuit configured to integrate the comparator output signal and to provide the integrated comparator output signal as the first reference signal to the source terminal of the first push-pull transistor, and a second bias control circuit configured to integrate the comparator output signal and to provide the integrated comparator output signal as the second reference signal to the source terminal of the second push-pull transistor.

In another example implementation of this embodiment, a first push-pull transistor of the pair of push-pull transistors is connected to a first reference potential via one or more first bias transistors configured to control the current flowing through the first push-pull transistor to the output terminal of the inverter stage, and another second push-pull transistor of the pair of push-pull transistors is connected to a second reference potential via another one or more second bias transistors configured to control the current flowing through the second push-pull transistor to the output terminal of the inverter stage. The one or more first bias transistors and the one or more second bias transistors may form variable resistances in this implementation. The amplifier circuit may for example further comprise a first bias control circuit configured to apply a bias signal to the gate terminal(s) of the one or more first bias transistors in response to the comparator output signal to thereby control the current flowing through the first push-pull transistor to the output terminal of the inverter stage; and a second bias control circuit configured to apply a bias signal to the gate terminal(s) of the one or more second bias transistors in response to the comparator output signal to thereby control the current flowing through the second push-pull transistor to the output terminal of the inverter stage.

In one example, the first and second bias control circuits are configured to integrate the comparator output signal and to provide the integrated comparator output signal as the bias signal to the gate terminals of the one or more first and second bias transistors, respectively.

In another example, the first bias control circuit is configured to selectively activate and deactivate a selected number of the first bias transistors in response to the comparator output signal to thereby control the current flowing through the first push-pull transistor to the output terminal of the inverter stage; and the second bias control circuit is configured to selectively activate and deactivate a selected number of the second bias transistors in response to the comparator output signal to thereby control the current flowing through the first push-pull transistor to the output terminal of the inverter stage. In this other example, the first and second bias control circuits may for example implement a counter or a switch matrix to selectively activate or deactivate the selected number of bias transistors.

In the different implementations mentioned above, each of the first and second bias control circuits may for example comprise an inverter circuit connected between two DC voltage references and a buffer capacitor connected between the output of the inverter circuit and one of the DC voltage references.

In another embodiment of the invention, the inverter stage comprises multiple cascaded inverters.

### BRIEF DESCRIPTION OF THE DRAWINGS

The present description will be better understood from the following detailed description read in light of the accompanying drawings, wherein like reference numerals are used to designate like parts in the accompanying description.

FIG. 1 shows an example tracking amplifier circuit adapted to drive a capacitive load;

FIG. 2 shows a schematic circuit implementation realizing a tracking amplifier 200 according to an embodiment of the invention;

FIG. 3 shows a schematic circuit diagram of a tracking amplifier 300 according to another example embodiment;

FIG. 4 shows a schematic circuit implementation realizing a tracking amplifier 400 according to another embodiment of the invention;

FIG. 5 shows a schematic circuit diagram of a tracking amplifier 500 according to another example embodiment;

FIG. 6 shows a schematic circuit implementation realizing a tracking amplifier 600 according to another embodiment of the invention;

FIGS. 7A and 7B show schematic circuit diagrams of two tracking amplifiers 700 and 750 according to another example embodiment;

FIG. 8A shows a schematic circuit implementation realizing a tracking amplifier 800 according to an embodiment of the invention;

FIG. 8B shows a schematic circuit diagram of a tracking amplifier 800′ according to another example embodiment;

FIG. 9A shows a schematic circuit implementation realizing a tracking amplifier 900 according to an embodiment of the invention;

FIG. 9B shows a schematic circuit diagram of a tracking amplifier 900′ according to another example embodiment;

FIGS. 10 and 11 show example waveforms in any one of the amplifier circuits 300, 500, 700, 750, 800′, 900′ as shown in FIGS. 3, 5, 7A, 7B, 8B and 9B ; and

FIGS. 12, 13 and 14 show further exemplary modifications of the output stage of the amplifiers in FIGS. 2 to 6, 7A, 7B, 8A, 8B, 9A and 9C according to different embodiments of the invention.

### DETAILED DESCRIPTION

Different embodiments of the invention will be outlined in the following in more detail. As noted, this disclosure generally relates to an amplifier circuit and design, which facilitates driving an inductive load and which does not require a complex feedback network for implementing the control loop. These advantages may further translate into an overall simpler design of the amplifier and smaller area on a die/chip when implementing the amplifier in an integrated circuit. Although the amplifier circuits may be simple in design, they can realize good linearity, which translates directly into the freedom from distortion of the amplified output signal. Accordingly, amplifiers designs according to the embodiments of the invention the output signals generated by the amplifier circuit may show only very limited deviations from the input signal or, depending on the gain factor, a multiple of the input signal.

The amplifier designs discussed herein may be particularly suitable for driving MEMS-based, SoC-based or SiP-based actuator systems, such as for example and not limited to acoustic pressure-generating (electrodynamic) devices that representing loads with an inductive component. For example, those acoustic pressure-generating devices may be based on principle of a Nanoscopic Electrostatic Drive (NED) is described, for example, in the patent application WO 2012/095185 A1. However, the application area of the amplifier designs discussed herein are not limited to this field of use.

One design aspect of the invention is to produce a time-continuous output current at the output terminal of the amplifier circuit and convert this time-continuous output current into a time-continuous output voltage that can be fed back as a feedback signal to a comparator to implement the control loop. As will become more apparent from the embodiments discussed herein, the amplifier circuit may produce a PWM voltage signal at the output and a time-continuous output current to flow towards an inductive load. The control loop is based on the conversion of the time-continuous current into a time-continuous voltage, which is implemented using a feedback network that is provided in between the output node of the amplifier circuit and one of the input nodes of the comparator. The feedback network can be arranged in parallel to the load branch or in series to the load branch. Furthermore, the amplifier design according to the different embodiments of the invention may use different voltage domains for the comparator, a buffer stage (if present) and the amplification stage.

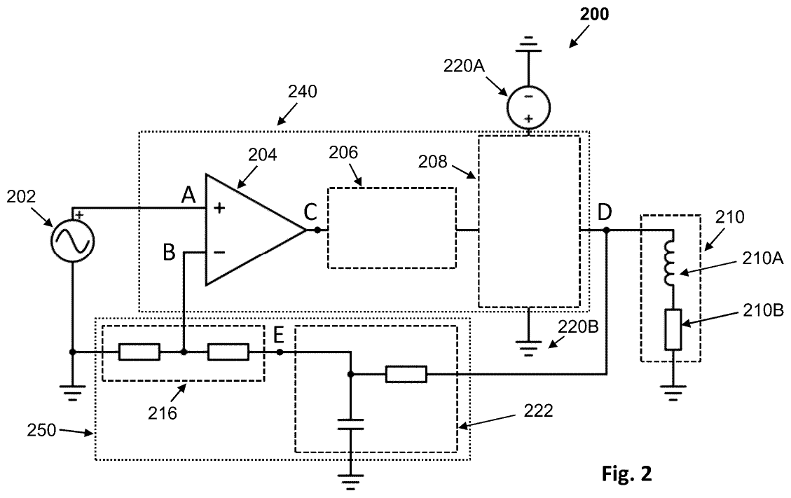

FIG. 2 shows a schematic circuit implementation realizing a tracking amplifier 200 according to an embodiment of the invention. The amplifier circuit 200 comprises an amplification stage 240 and a feedback stage 250. The amplification stage 240 comprises a comparator 204, which has a non-inverting terminal A and an inverting terminal B as input terminals. An input signal 202 is provided to the input terminal A. The input signal 202 may be a time continuous voltage signal. When using the amplifier circuit 200 for driving an acoustic-pressure generating device, for example, within a headphone, in-ear device, etc. the input signal 202 may be an audio signal or sound signal that is to drive the actuator(s) of the acoustic-pressure generating device to generate the desired acoustic pressure in the audible and/or non-audible frequency range of the frequency spectrum.

The comparator 204 compares the signals (i.e. the voltages/potentials) applied to its input terminals A and B and provides either a high or low signal at its output terminal C that indicates the result of the comparison. The comparator 204's output signal is provided to a buffer circuit 206. The buffer circuit 206 is optional and may not be present. The buffer circuit 206 may for example include one or more buffer circuits that may for example be used to perform level shifting of the output signals at output terminal C to adapt the signal level (e.g. voltage/potential) and/or the signal current to the desired range for driving the push-pull stage 208. The push-pull stage 208 is used to amplify the output signal of the comparator 204 (as processed by the optional buffer circuit 206) and provides the output signal of the amplifier 200 at the output terminal D.

The push-pull stage 208 generates a PWM signal relative to the reference potentials 220A and 220B and responsive to the output signal of the comparator 204, which is used as a control signal of the push-pull stage 208. Reference potential 220B is exemplarily shown as GND. The reference potentials 220A and 220B may also be referred as VDD and VSS, respectively. The reference potentials 220A and 220B may be adjustable, programmable or controllable.

The output signal provided by the amplifier circuit 200 at the output terminal D may be a PWM voltage signal, which causes a time-continuous current signal to flow into node D or from the node D into the amplifier circuit 200. The output signal of the amplifier circuit 200 at terminal D is applied to an inductive load 210, which is modelled for exemplary purposes by an inductance 210A (L_{load}) and a resistance 210B (R_{load}).

The output signal of the amplifier circuit 200 at terminal D is applied to the feedback stage 250. In the example embodiment of FIG. 2, the feedback stage 250 comprises a feedback network 222 and a voltage divider 216. The feedback network 222 is a circuit configured to convert the time-continuous current signal to flow into node D or from the node D into the amplifier circuit 200 into a time-continuous voltage signal. The time-continuous voltage signal is provided at the node E and is applied to the voltage divider 216. The voltage divider 216 adjusts the time-continuous voltage signal that is provided at node E to an appropriate voltage level for application to the inverting terminal B of the comparator 204.

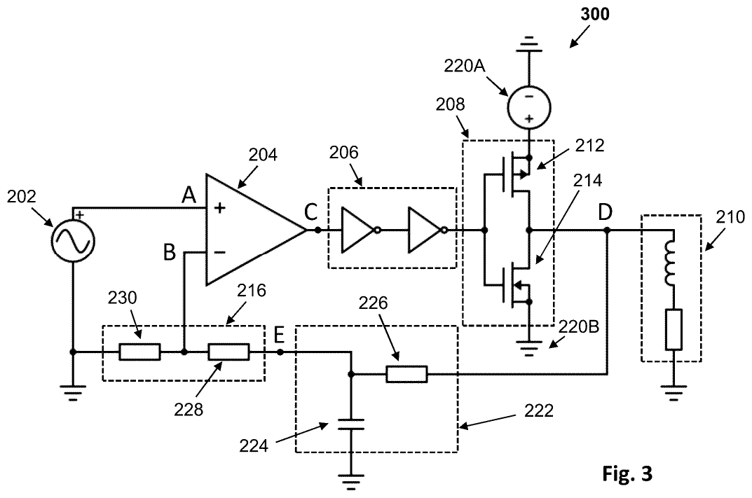

FIG. 3 shows a schematic circuit diagram of a tracking amplifier 300 according to another example embodiment. The amplifier circuit 300 may be considered a more detailed implementation of the amplifier circuit 200 shown in FIG. 2. The buffer circuit 206 in FIG. 2, which is optional, is shown to comprise two inverter stages that perform level shifting of the output signal of the comparator 204 at terminal C. The push-pull stage 208 is realized by a simple inverter stage. In other embodiments, push-pull stage 208 may be implemented using multiple cascaded inverters.

The inverter stage is formed by a pair of transistors 212, 214, which are—in this example—a n-type transistor (e.g. NPN) and a p-type transistor (e.g. PNP). The transistors 212, 214 are connected in series between the reference potentials 220A and 220B. The drain terminals of the transistors 212, 214 are connected to each other and to the output terminal D. The emitter terminals of the transistors 212, 214 are connected to the reference potentials 220A and 220B, respectively. The gate terminals of the transistors 212, 214 are coupled to the terminal C providing the output signal of the comparator 204 via the buffer circuit 206 as described above. In some embodiments, the transistors 212, 214 may be small signals transistors or small switching transistors, which may be for example implemented as Bipolar Junction Transistors (BJTs) (e.g. NPN- and PNP-transistors). However, it is also possible to use Field Effect Transistors (FETs), e.g. Junction FETs (JFETs) or Metal Oxide Semiconductor FETs (MOSFETs). In principle, the transistors 212, 214 could also be implemented using other switching elements, e.g. using power transistors.

Further, transistors 212, 214 are shown to be of different type (p-type and n-type, respectively) and are therefore driven by a same control signal corresponding to the output signal at node C of the comparator 204. However, both transistors 212, 214 may be implemented using the same transistor type, if the control signal corresponding to the output signal at node C of the comparator 204 applied to the gate terminal of one of the transistors 212, 214 is inverted (e.g. in an inverter). The control signal to the other gate terminal may be used “as is” or a delay element could be added to compensate for a phase difference between the inverted control signal and the non-inverted control signal, if this phase difference is critical to the proper operation of the amplifications stage 240. In other embodiments and application scenarios, the push-pull stage 208 could be replaced by a single transistor having its source terminal connected to the reference potentials 220A or 220B and a gate terminal receiving a control signal from the node C. In this case, the drain terminal may be connected to the output node D.

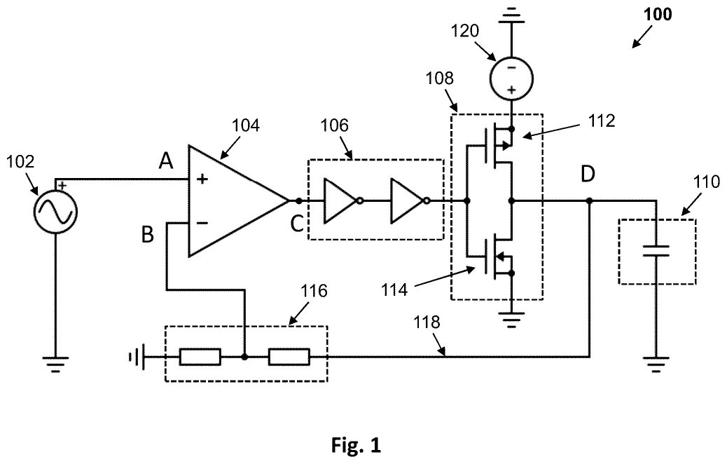

Like in FIG. 1, the input signal at the input A of the comparator 204 is compared with the feedback signal at the terminal B of the comparator 204 which is based on the time-continuous output signal of the amplifier circuit 300 at node D. Depending on the two input signals of the comparator 204, a “digital” signal with a high or low level is generated at the output C of the comparator 204. This resulting digital signal may be amplified in the buffer circuit 206 (if present) and is in turn used to control the push-pull inverter stage 208 by driving the gate terminals of the transistors 212, 214. A PWM sequence is produced at output terminal D of the amplifier 300. To convert the current through the inductive load 210 (impedance L_{load} and line resistance R_{load}) into a time-continuous voltage, the feedback network 222 is implemented by a simple low-pass filter. The low-pass filter is implemented by means of an RC-element, i.e. the resistor 226 (R_{filter}) and capacitor 224 (C_{filter}) which are connected in parallel with the load branch through the inductive load 210. Due to the time-continuous feedback current from D that continuously charges or discharges capacitance 224, the voltage potential at node E will also change over time. The low-pass filtering of a part of the current on the output side node D again produces a usable, time-continuous voltage that is fed back via the voltage divider 216 in the feedback loop. The exemplary voltage divider 216 is formed from two resistors 228 (Rdiv1) and 230 (Rdiv2) and the center tap of the voltage divider in between the two resistors 228, 230 is connected to the inverting terminal B of the comparator 204 thereby completing the control loop. The voltage divider 216 could also be implemented using two capacitances. The ratio of the resistances of the resistors 228 and 230 can be set, controlled or designed to achieve the desired amplification gain of the amplifier circuit.

The low-pass filter 224, 226 of the feedback network 222 may also be implemented as an LC element, for example. Depending on the field of use, the additional inductance of the LC element may not be desired. Another alternative implementation of the feedback network 222 may be a switched-capacitor filter.

In order for the control loop to function optimally, i.e. the amplified target current on the output side at node D follows the corresponding input signal 202 on the input side, according to some embodiments, the load branch time constant of L_{load} divided by R_{load} is preferably equal the parallel low-pass filter time constant of R_{filter} multiplied by C_{filter}, i.e. L_{load}/R_{load}=R_{filter}·C_{filter}. The impedance of the feedback branch 250 may be very high so that the power flowing into the feedback stage 250 is minimized. This allows for very high energy efficiency of the amplifier 200, 300 and at the same time the load 210 on the output side is not changed due to the parallel connection of the feedback network 222 and the load 210.

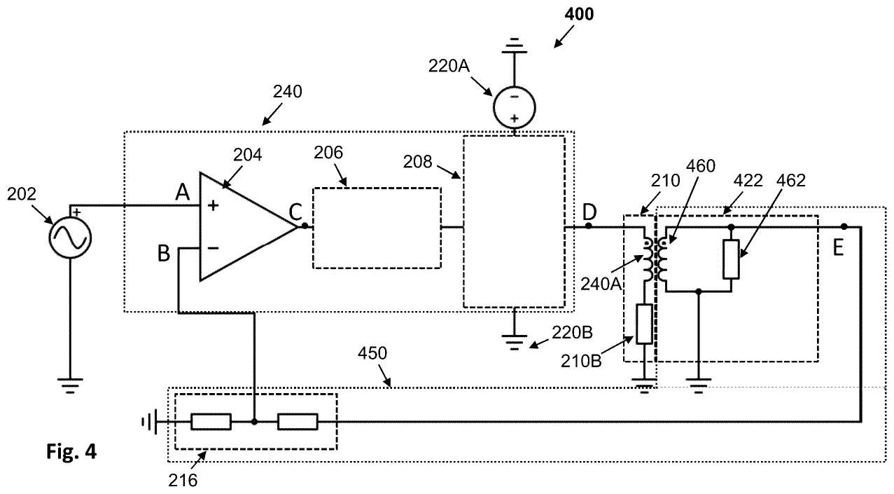

FIG. 4 shows another schematic circuit implementation realizing a tracking amplifier 400 according to an embodiment of the invention. The amplifier circuit 400 comprises an amplification stage 240 and a feedback stage 450. The amplification stage 240 comprises a comparator 204, which has a non-inverting terminal A and an inverting terminal B as input terminals. An input signal 202 is provided to the input terminal A. The input signal 202 may be a time continuous voltage signal. When using the amplifier circuit 400 for driving an acoustic-pressure generating device, for example, within a headphone, in-ear device, etc. the input signal 202 may be an audio signal or sound signal that is to drive the actuator(s) of the acoustic-pressure generating device to generate the desired acoustic pressure in the audible and/or non-audible frequency range of the frequency spectrum.

The comparator 204 compares the signals (i.e. the voltages/potentials) applied to its input terminals A and B and provides either a high or low signal at its output terminal C that indicates the result of the comparison. The comparator 204's output signal is provided to a buffer circuit 206. The buffer circuit 206 is optional and may not be present. The buffer circuit 206 may for example include one or more buffer circuits that may for example be used to perform level shifting of the output signals at output terminal C to adapt the signal level (e.g. voltage/potential) and/or the signal current to the desired range for driving the push-pull stage 208. The push-pull stage 208 is used to amplify the output signal of the comparator 204 (as processed by the optional buffer circuit 206) and provides the output signal of the amplifier 400 at the output terminal D.

The push-pull stage 208 generates a PWM signal relative to the reference potentials 220A and 220B and responsive to the output signal of the comparator 204, which is used as a control signal of the push-pull stage 208. Reference potential 220B is exemplarily shown as GND. The reference potentials 220A and 220B may also be referred as VDD and VSS, respectively. The reference potentials 220A and 220B may be adjustable, programmable or controllable.

The output signal provided by the amplifier circuit 400 at the output terminal D may be a PWM voltage signal, which causes a time-continuous current signal to flow into node D or from the node D into the amplifier circuit 400. The output signal of the amplifier circuit 400 at terminal D is applied to an inductive load 210, which is modelled for exemplary purposes by an inductance 210A (L_{load}) and a resistance 210B (R_{load}).

The output signal of the amplifier circuit 400 at terminal D is applied to the feedback stage 450. In the example embodiment of FIG. 4, the feedback stage 450 comprises a feedback network 422 and a voltage divider 216. The feedback network 422 is a circuit configured to convert the time-continuous current signal to flow into node D or from the node D into the amplifier circuit 400 into a time-continuous voltage signal. The feedback network 422 is connected in parallel to the inductive load 210. The time-continuous voltage signal is provided at the node E and is applied to the voltage divider 216. The voltage divider 216 adjusts the time-continuous voltage signal that is provided at node E to an appropriate voltage level for application to the inverting terminal B of the comparator 204.

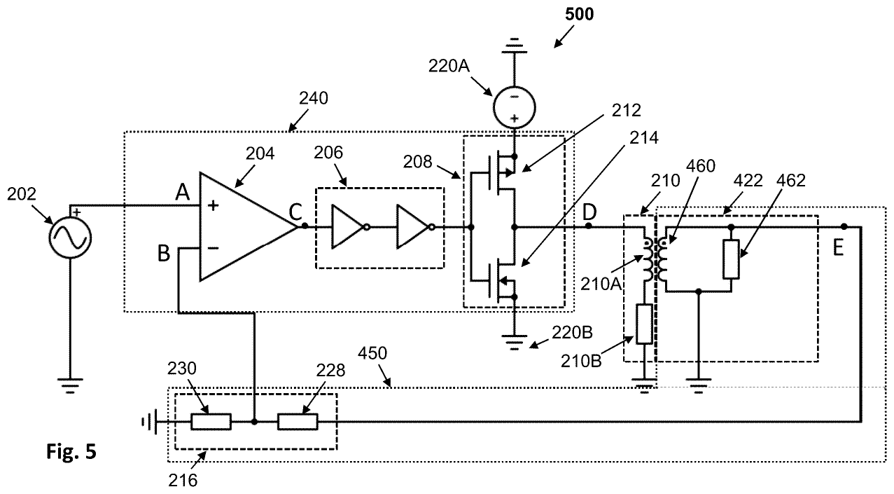

FIG. 5 shows a schematic circuit diagram of a tracking amplifier 500 according to another example embodiment. The amplifier circuit 500 may be considered a more detailed implementation of the amplifier circuit 400 shown in FIG. 4. The buffer circuit 206 in FIG. 4, which is optional, is shown to comprise two inverter stages that perform level shifting of the output signal of the comparator 204 at terminal C. The push-pull stage 208 is realized by a simple inverter stage. In other embodiments, push-pull stage 208 may be implemented using multiple cascaded inverters.

The inverter stage is formed by a pair of transistors 212, 214, which are—in this example—a n-type transistor (e.g. NPN) and a p-type transistor (e.g. PNP). The transistors 212, 214 are connected in series between the reference potentials 220A and 220B. The drain terminals of the transistors 212, 214 are connected to each other and to the output terminal D. The emitter terminals of the transistors 212, 214 are connected to the reference potentials 220A and 220B, respectively. The gate terminals of the transistors 212, 214 are coupled to the terminal C providing the output signal of the comparator 204 via the buffer circuit 206 as described above. In some embodiments, the transistors 212, 214 may be small signals transistors or small switching transistors, which may be for example implemented as Bipolar Junction Transistors (BJTs) (e.g. NPN- and PNP-transistors). However, it is also possible to use Field Effect Transistors (FETs), e.g. Junction FETs (JFETs) or Metal Oxide Semiconductor FETs (MOSFETs). In principle, the transistors 212, 214 could also be implemented using other switching elements, e.g. using power transistors.

Further, transistors 212, 214 are shown to be of different type (p-type and n-type, respectively) and are therefore driven by a same control signal corresponding to the output signal at node C of the comparator 204. However, both transistors 212, 214 may be implemented using the same transistor type, if the control signal corresponding to the output signal at node C of the comparator 204 applied to the gate terminal of one of the transistors 212, 214 is inverted (e.g. in an inverter). The control signal to the other gate terminal may be used “as is” or a delay element could be added to compensate for a phase difference between the inverted control signal and the non-inverted control signal, if this phase difference is critical to the proper operation of the amplifications stage 240. In other embodiments and application scenarios, the push-pull stage 208 could be replaced by a single transistor having source terminal connected to the reference potentials 220A or 220B and a gate terminal receiving a control signal from the node C. In this case, the drain terminal may be connected to the output node D.

Like in FIG. 1, the input signal at the input A of the comparator 204 is compared with the feedback signal at the terminal B of the comparator 204 which is based on the time-continuous output signal of the amplifier circuit 500 at node D. Depending on the two input signals of the comparator 204, a “digital” signal with a high or low level is generated at the output C of the comparator 204. This resulting digital signal may be amplified in the buffer circuit 206 (if present) and is in turn used to control the push-pull inverter stage 208 by driving the gate terminals of the transistors 212, 214. A PWM sequence is produced at output terminal D of the amplifier 500. To convert the current through the inductive load 210 (impedance L_{load} and line resistance R_{load}) into a time-continuous voltage, the feedback network 422, which comprises another inductor 460 (impedance L₂) and a resistor 462) (resistance R_{convert}), is connected in parallel with the load 210. The inductances 210A and 460 are arranged in such a way that the magnetic field can be coupled through the inductances 210A and 460. Inductances 210A and 460 of the inductive load 210 and the feedback network 422, respectively, effectively create a transformer with a primary-side winding being formed by the inductance 210A and a secondary-side winding being formed by the inductance 460. The time-continuous charging or discharging current flowing into or from node D is mirrored to the node E by the transformer. The turns ratio between the primary winding (inductance 210A) and secondary winding (inductance 460) and their magnetic coupling determines the ratio of the current at node D and the current mirrored into the feedback network 422. The resistor 462 (R_{convert}) converts this current mirrored into the feedback network 422 into a time-continuous voltage signal. The resistor 462 is connected in parallel to the voltage divider 216. The exemplary voltage divider 216 is formed from two resistors 216 (Rdiv1) and 230 (Rdiv2) and the center tap of the voltage divider in between the two resistors 216, 230 is connected to the inverting terminal B of the comparator 204 thereby completing the control loop. The voltage divider 216 could also be implemented using two capacitances. The ratio of the resistances of the resistors 462, 216 and 230 and/or the turns ratio of the inductance 210A and inductance 460 can individually or jointly be set, controlled or designed to achieve the desired amplification gain of the amplifier circuit.

For high energy efficiency, the current in the feedback path through the feedback network 422, should be substantially smaller than the desired output current through the inductive load 210. To put it different, the number of windings N_{L2} of the inductance 460 should be M times the number of windings N_{Lload} of the inductance 210A of the inductive load 210. For example, with M=100, the current through the inductance 460 is reduced by a factor of M in comparison to the current through the inductive load 210. In example embodiments, M≥50, preferably, M≥100, more preferably M≥200, and even more preferably M≥500.

In order for the control loop to function optimally, i.e. the amplified target current on the output side at node D follows the input signal 202 on the input side, according to some embodiments the voltage across the resistor 462 should be (substantially) equal to the voltage of the input signal 202 on the input side of the amplifier circuit 500. For this, the resistance R_{convert} of the resistor 462 may be selected, set, controlled or configured to have a value that is (substantially) equal to the product of the line resistance R_{load} and the factor M (R_{convert}=M·R_{load}). The impedance of the feedback branch (216 and 422) may thus be very high so that the power flowing into the feedback stage is minimized. This allows for very high energy efficiency of the amplifier 400, 500 and at the same time the load 210 on the output side is not changed due to the parallel connection of the feedback network 422 and the load 210.

In the example embodiment shown in FIG. 5, the discharge of the output current at terminal D can be through the inductive load 210. Hence, in an alternative implementation, it is possible to replace the inverter stage 208 by a transistor (e.g. transistor 212 only, and “cancelling” the transistor 214, or vice versa), which has its drain terminal connected to the output terminal D.

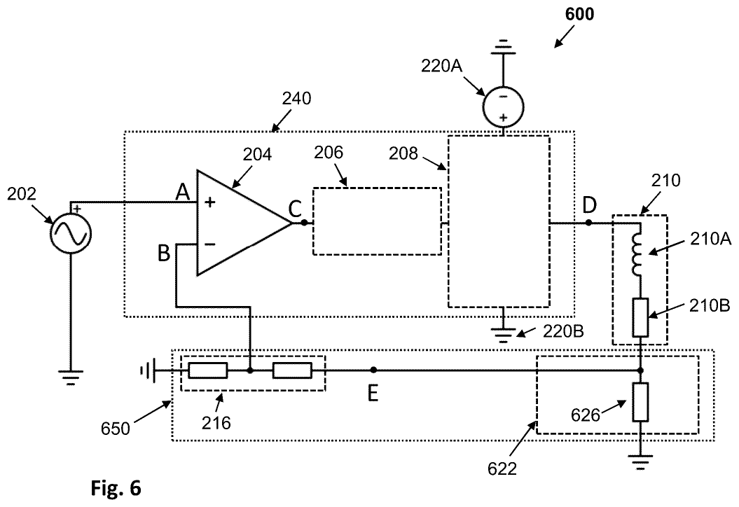

FIG. 6 shows yet another schematic circuit implementation realizing a tracking amplifier 600 according to an embodiment of the invention. The amplifier circuit 600 comprises an amplification stage 240 and a feedback stage 650. The amplification stage 240 comprises a comparator 204, which has a non-inverting terminal A and an inverting terminal B as input terminals. An input signal 202 is provided to the input terminal A. The input signal 202 may be a time continuous voltage signal. When using the amplifier circuit 600 for driving an acoustic-pressure generating device, for example, within a headphone, in-ear device, etc. the input signal 202 may be an audio signal or sound signal that is to drive the actuator(s) of the acoustic-pressure generating device to generate the desired acoustic pressure in the audible and/or non-audible frequency range of the frequency spectrum.

The comparator 204 compares the signals (i.e. the voltages/potentials) applied to its input terminals A and B and provides either a high or low signal at its output terminal C that indicates the result of the comparison. The comparator 204's output signal is provided to a buffer circuit 206. The buffer circuit 206 is optional and may not be present. The buffer circuit 206 may for example include one or more buffer circuits that may for example be used to perform level shifting of the output signals at output terminal C to adapt the signal level (e.g. voltage/potential) and/or the signal current to the desired range for driving the push-pull stage 208. The push-pull stage 208 is used to amplify the output signal of the comparator 204 (as processed by the optional buffer circuit 206) and provides the output signal of the amplifier 600 at the output terminal D.

The push-pull stage 208 generates a PWM signal relative to the reference potentials 220A and 220B and responsive to the output signal of the comparator 204, which is used as a control signal of the push-pull stage 208. Reference potential 220B is exemplarily shown as GND. The reference potentials 220A and 220B may also be referred as VDD and VSS, respectively. The reference potentials 220A and 220B may be adjustable, programmable or controllable.

The output signal provided by the amplifier circuit 600 at the output terminal D may be a PWM voltage signal, which causes a time-continuous current signal to flow into node D or from the node D into the amplifier circuit 600. The output signal of the amplifier circuit 600 at terminal D is applied to an inductive load 210, which is modelled for exemplary purposes by an inductance 210A (L_{load}) and a resistance 210B (R_{load}).

The output signal of the amplifier circuit 600 at terminal D is applied to the feedback stage 650. In the example embodiment of FIG. 6, a feedback stage 650 comprises a feedback network 622 and a voltage divider 216. The feedback network 622 is a circuit configured to convert the time-continuous current signal to flow into node D or from the node D into the amplifier circuit 600 into a time-continuous voltage signal. The feedback network 622 is connected in series to the inductive load 210. The time-continuous voltage signal is provided at the node E and is applied to the voltage divider 216. The voltage divider 216 adjusts the time-continuous voltage signal that is provided at node E to an appropriate voltage level for application to the inverting terminal B of the comparator 204.

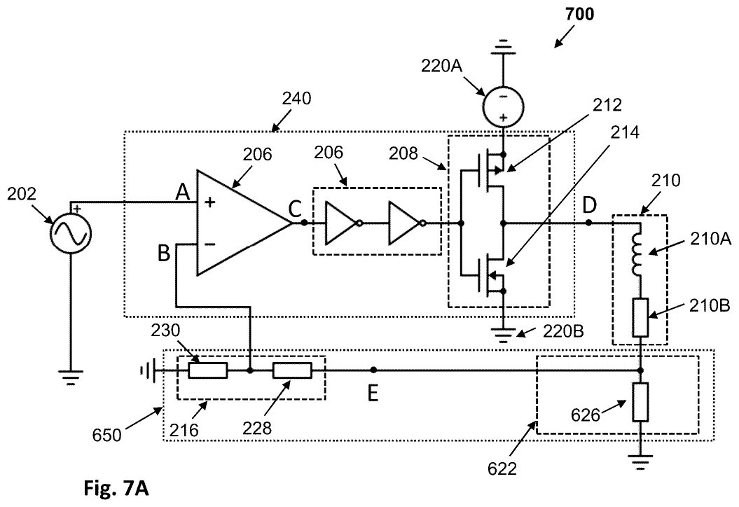

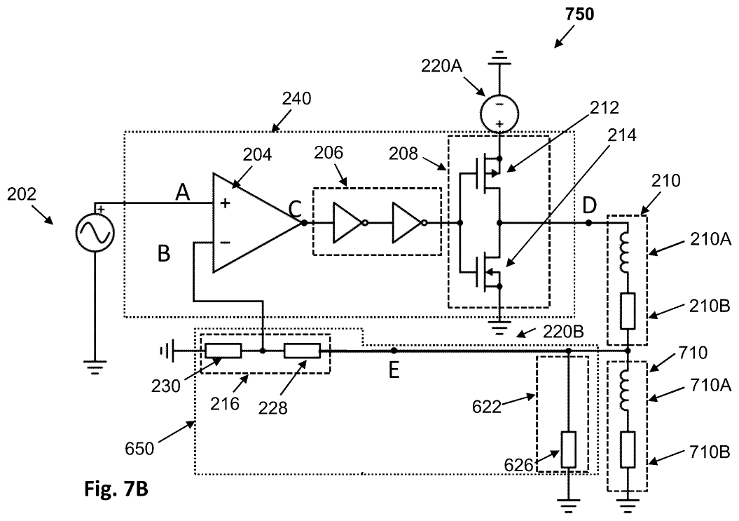

FIG. 7A shows a schematic circuit diagram of a tracking amplifier 700 according to another example embodiment. The amplifier circuit 700 may be considered a more detailed implementation of the amplifier circuit 600 shown in FIG. 6. The buffer circuit 206 in FIG. 6, which is optional, is shown to comprise two inverter stages that perform level shifting of the output signal of the comparator 204 at terminal C. The push-pull stage 208 is realized by a simple inverter stage. In other embodiments, push-pull stage 208 may be implemented using multiple cascaded inverters.

The inverter stage is formed by a pair of transistors 212, 214, which are—in this example—a n-type transistor (e.g. NPN) and a p-type transistor (e.g. PNP). The transistors 212, 214 are connected in series between the reference potentials 220A and 220B. The drain terminals of the transistors 212, 214 are connected to each other and to the output terminal D. The emitter terminals of the transistors 212, 214 are connected to the reference potentials 220A and 220B, respectively. The gate terminals of the transistors 212, 214 are coupled to the terminal C providing the output signal of the comparator 204 via the buffer circuit 206 as described above. In some embodiments, the transistors 212, 214 may be small signals transistors or small switching transistors, which may be for example implemented as Bipolar Junction Transistors (BJTs) (e.g. NPN- and PNP-transistors). However, it is also possible to use Field Effect Transistors (FETs), e.g. Junction FETs (JFETs) or Metal Oxide Semiconductor FETs (MOSFETs). In principle, the transistors 212, 214 could also be implemented using other switching elements, e.g. using power transistors.

Further, transistors 212, 214 are shown to be of different type (p-type and n-type, respectively) and are therefore driven by a same control signal corresponding to the output signal at node C of the comparator 204. However, both transistors 212, 214 may be implemented using the same transistor type, if the control signal corresponding to the output signal at node C of the comparator 204 applied to the gate terminal of one of the transistors 212, 214 is inverted (e.g. in an inverter). The control signal to the other gate terminal may be used “as is” or a delay element could be added to compensate for a phase difference between the inverted control signal and the non-inverted control signal, if this phase difference is critical to the proper operation of the amplifications stage 240. In other embodiments and application scenarios, the push-pull stage 208 could be replaced by a single transistor having source terminal connected to the reference potentials 220A or 220B and a gate terminal receiving a control signal from the node C. In this case, the drain terminal may be connected to the output node D.

Like in FIG. 1, the input signal at the input A of the comparator 204 is compared with the feedback signal at the terminal B of the comparator 204 which is based on the time-continuous output signal of the amplifier circuit 700 at node D. Depending on the two input signals of the comparator 204, a “digital” signal with a high or low level is generated at the output C of the comparator 204. This resulting digital signal may be amplified in the buffer circuit 206 (if present) and is in turn used to control the push-pull inverter stage 208 by driving the gate terminals of the transistors 212, 214. A PWM sequence is produced at output terminal D of the amplifier 700. To convert the current through the inductive load 210 (impedance L_{load} and line resistance R_{load}) into a time-continuous voltage, the feedback network 622, which comprises a resistor 626 (resistance R_{convert}), is connected in series with the load 210. The resistor 626 converts the current through the inductive load 210 into a time-continuous voltage signal at the terminal E, relative to the reference potential. The resistor 626 is connected between an output terminal of the inductive load 210 and the reference potential. The voltage at the terminal E is provided to the voltage divider 216. The exemplary voltage divider 216 is formed from two resistors 216 (Rdiv1) and 230 (Rdiv2) and the center tap of the voltage divider in between the two resistors 216, 230 is connected to the inverting terminal B of the comparator 204 thereby completing the control loop. The voltage divider 216 could also be implemented using two capacitances. The ratio of the resistances of the resistors 626, 216 and 230 can be set, controlled or designed to achieve the desired amplification gain of the amplifier circuit.

The main advantage, the example amplifier 700 in FIG. 7A is its ease of implementation. Yet, the line resistance R_{load} of the load 210 and the conversion resistance R_{convert} of the resistor 626 form another voltage divider. This additional voltage divider limits the maximum current through the load branch, and also requires a higher output voltage at node D compared to exemplary implementations where the inductive load 210 is connected to the reference potential directly, in order to compensate for the additional voltage drop across the resistor 626 (R_{convert}). It should also be noted that the charging and discharging constant of the load inductance 210A (L_{load}) over time is influenced by the resistance R_{convert} of the resistor 626. A larger resistance R_{convert} of the resistor 626 decreases the time constant, while a smaller resistance R_{convert} of the resistor 626 increases it. The impedance of the voltage divider 216 in the feedback path can again be chosen to be very high so that the power flowing into the feedback stage is minimized. This allows for very high energy efficiency of the amplifier 600, 700.

FIG. 7B shows a schematic circuit diagram of a tracking amplifier 750 according to another example embodiment. The amplifier circuit 750 may be considered a more detailed implementation of the amplifier circuit 600 shown in FIG. 6. The tracking amplifier 750 is substantially similar to the tracking amplifier 700 of FIG. 7A. The main difference between the two embodiments in FIGS. 7A and 7B is the connection of the feedback stage 650 to the inductive load at the output of the amplifier. In the embodiment of FIG. 7B, the inductive load is formed by two load components 210 and 710, which are connected in series between the output terminal D and the reference potential. The two components 210 and 710 may have an impedance L_{load} shown as two inductances 210A and 210A and line resistance R_{load} formed by the resistive elements 210B and 210B. For example, the two inductances 210A and 210A may be realized as a coil with a symmetrical center tap. Advantageously, the impedance of the load component 210A is L_{load}/2 and the impedance of load component 210A is also L_{load}/2; the line resistance of the resistance component 210B is R_{load}/2 and the line resistance of the resistance component 210B is also R_{load}/2. Of course, any other asymmetrical taps or the combination of two separate inductances 210A, 210A and/or resistances 210B and 210B can be implemented. Similar to the implementation in FIG. 7A, the resistor 626 (resistance R_{convert}) is used in parallel with the lower inductance. The resistor R_{convert} generates a usable time-continuous voltage from the current on the output side and provides the same to the voltage divider 216. The main advantage, the example amplifier 750 in FIG. 7B is again the ease of implementation. Furthermore, and in comparison to the embodiment of FIG. 7A, the additional voltage divider at the output of the amplifier 750 is now formed by the resistance 210B (with R_{load}/2 Vs. R_{load} in the amplifier 700) and the resistance 626, which changes the voltage division at the center tap connected to the terminal E. This reduces the maximum current through the load branch, and also requires a higher output voltage at node D compared to exemplary implementations where the inductive load 210 is connected to the reference potential directly, in order to compensate for the additional current path via resistor 626 (R_{convert}). Although the resistance R_{convert} of the resistor 626 can be chosen to be very large, thereby reducing the unwanted cross current, a small change in the current through the load branch causes a correspondingly large change in the feedback voltage at node E. If this imbalance impairs the function of the control loop, this potentially undesirable change in the feedback signal voltage at terminal E may be compensated by an appropriate ratio of the voltage divider 216. The impedance of the voltage divider 216 in the feedback path can again be chosen to be very high. It should also be noted that the charging and discharging time constant of the load inductance 210A, 210A over time is influenced by the resistance R_{convert} of the resistor 626.

In both example embodiments shown in FIGS. 7A and 7B, the discharge of the output current at terminal D can be through the inductive load. Hence, in an alternative implementation, it is possible to replace the inverter stage 208 by a transistor (e.g. transistor 212 only, and “cancelling” the transistor 214, or vice versa), which has its drain terminal connected to the output terminal D.

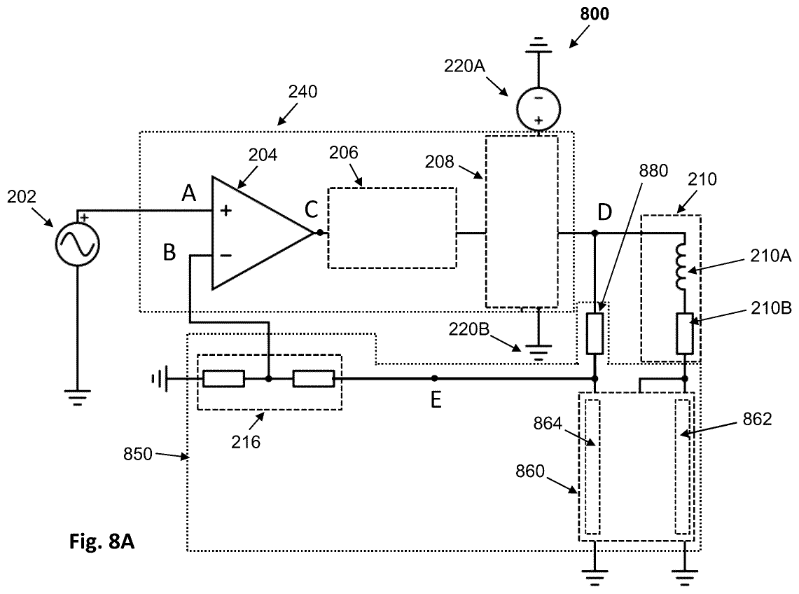

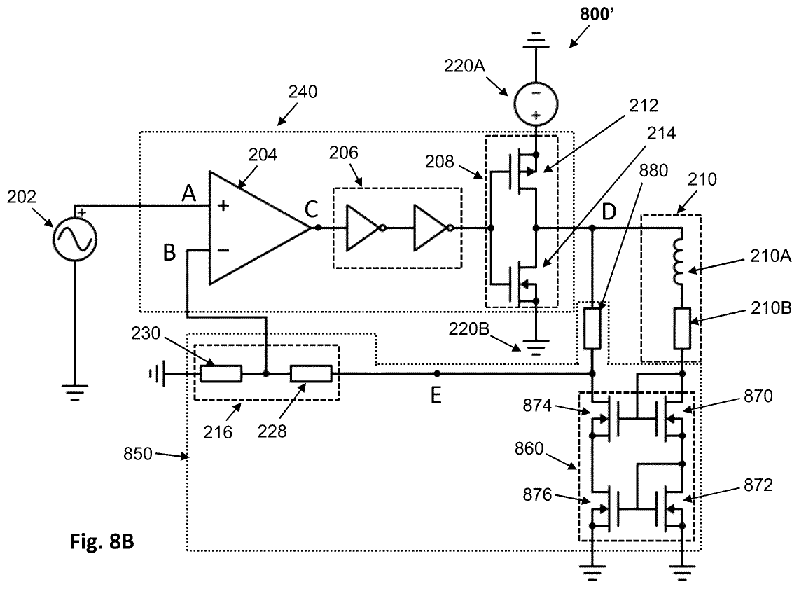

FIG. 8A shows a schematic circuit implementation realizing a tracking amplifier 800 according to an embodiment of the invention. The amplifier circuit 800 comprises an amplification stage 240 and a feedback stage 850. The amplification stage 240 comprises a comparator 204, which has a non-inverting terminal A and an inverting terminal B as input terminals. An input signal 202 is provided to the input terminal A. The input signal 202 may be a time continuous voltage signal. When using the amplifier circuit 800 for driving an acoustic-pressure generating device, for example, within a headphone, in-ear device, etc. the input signal 202 may be an audio signal or sound signal that is to drive the actuator(s) of the acoustic-pressure generating device to generate the desired acoustic pressure in the audible and/or non-audible frequency range of the frequency spectrum.

The comparator 204 compares the signals (i.e. the voltages/potentials) applied to its input terminals A and B and provides either a high or low signal at its output terminal C that indicates the result of the comparison. The comparator 204's output signal is provided to a buffer circuit 206. The buffer circuit 206 is optional and may not be present. The buffer circuit 206 may for example include one or more buffer circuits that may for example be used to perform level shifting of the output signals at output terminal C to adapt the signal level (e.g. voltage/potential) and/or the signal current to the desired range for driving the push-pull stage 208. The push-pull stage 208 is used to amplify the output signal of the comparator 204 (as processed by the optional buffer circuit 206) and provides the output signal of the amplifier 800 at the output terminal D.

The push-pull stage 208 generates a PWM signal relative to the reference potentials 220A and 220B and responsive to the output signal of the comparator 204, which is used as a control signal of the push-pull stage 208. Reference potential 220B is exemplarily shown as GND. The reference potentials 220A and 220B may also be referred as VDD and VSS, respectively. The reference potentials 220A and 220B may be adjustable, programmable or controllable.

The output signal provided by the amplifier circuit 800 at the output terminal D may be a PWM voltage signal, which causes a time-continuous current signal to flow into node D or from the node D into the amplifier circuit 800. The output signal of the amplifier circuit 800 at terminal D is applied to an inductive load 210, which is modelled for exemplary purposes by an inductance 210A (L_{load}) and a resistance 210B (R_{load}).

The output signal of the amplifier circuit 800 at terminal D is applied to the feedback stage 850. In the example embodiment of FIG. 8A, the feedback stage 850 comprises a current mirror 860, a resistor 880 and a voltage divider 216. The current mirror 860 is connected to the resistor 880 and the inductive load 210. The current mirror 860 mirrors the load current flowing from the node D through the inductive load 210 and the first path 862 of the current mirror 860 to the reference potential to the second path 864 of the current mirror 860. Hence, a mirrored time-continuous current signal flowing in the second path 864 is proportional to the load current flowing from the node D through the inductive load 210 and the first path 862 of the current mirror 860. Due to the impedance of the voltage divider 216 being substantially higher than that of the second path 864 of the current mirror 860, the current flowing through the resistor 880 will thus be substantially the same as the mirrored current signal in the second path 864 of the current mirror 860. The output terminal of the resistor 880 (i.e. its terminal that is not connected to node D), which connects to node E, provides a time-continuous voltage to the voltage divider 216 which is equivalent to the mirrored time-continuous current signal through the resistor 880. The other terminal of the resistor 880 is connected to the output node D. The resistor 880 thus converts the mirrored time-continuous current signal to flow into node D or from the node D into the amplifier circuit 800 into a time-continuous voltage signal. The mirrored time-continuous voltage signal from the resistor 880 is provided at the node E and is applied to the voltage divider 216. The voltage divider 216 adjusts the mirrored time-continuous voltage signal that is provided at node E to an appropriate voltage level for application to the inverting terminal B of the comparator 204.

FIG. 8B shows a schematic circuit diagram of a tracking amplifier 800′ according to another example embodiment. The amplifier circuit 800′ may be considered a more detailed implementation of the amplifier circuit 800 shown in FIG. 8A. The buffer circuit 206 in FIG. 8B, which is optional, is shown to comprise two inverter stages that perform level shifting of the output signal of the comparator 204 at terminal C. The push-pull stage 208 is realized by a simple inverter stage. In other embodiments, push-pull stage 208 may be implemented using multiple cascaded inverters.

The inverter stage is formed by a pair of transistors 212, 214, which are—in this example—a n-type transistor (e.g. NPN) and a p-type transistor (e.g. PNP). The transistors 212, 214 are connected in series between the reference potentials 220A and 220B. The drain terminals of the transistors 212, 214 are connected to each other and to the output terminal D. The emitter terminals of the transistors 212, 214 are connected to the reference potentials 220A and 220B, respectively. The gate terminals of the transistors 212, 214 are coupled to the terminal C providing the output signal of the comparator 204 via the buffer circuit 206 as described above. In some embodiments, the transistors 212, 214 may be small signals transistors or small switching transistors, which may be for example implemented as Bipolar Junction Transistors (BJTs) (e.g. NPN- and PNP-transistors). However, it is also possible to use Field Effect Transistors (FETs), e.g. Junction FETs (JFETs) or Metal Oxide Semiconductor FETs (MOSFETs). In principle, the transistors 212, 214 could also be implemented using other switching elements, e.g. using power transistors.

Further, transistors 212, 214 are shown to be of different type (p-type and n-type, respectively) and are therefore driven by a same control signal corresponding to the output signal at node C of the comparator 204. However, both transistors 212, 214 may be implemented using the same transistor type, if the control signal corresponding to the output signal at node C of the comparator 204 applied to the gate terminal of one of the transistors 212, 214 is inverted (e.g. in an inverter). The control signal to the other gate terminal may be used “as is” or a delay element could be added to compensate for a phase difference between the inverted control signal and the non-inverted control signal, if this phase difference is critical to the proper operation of the amplification stage 240. In other embodiments and application scenarios, the push-pull stage 208 could be replaced by a single transistor having source terminal connected to the reference potentials 220A or 220B and a gate terminal receiving a control signal from the node C. In this case, the drain terminal may be connected to the output node D.

Like in FIG. 1, the input signal at the input A of the comparator 204 is compared with the feedback signal at the terminal B of the comparator 204 which is based on the time-continuous output signal of the amplifier circuit 900 at node D. Depending on the two input signals of the comparator 204, a “digital” signal with a high or low level is generated at the output C of the comparator 204. This resulting digital signal may be amplified in the buffer circuit 206 (if present) and is in turn used to control the push-pull inverter stage 208 by driving the gate terminals of the transistors 212, 214. A PWM sequence is produced at output terminal D of the amplifier 800′. To convert the current through the inductive load 210 (impedance L_{load} and line resistance R_{load}) into a time-continuous voltage, a resistor 880 is provided, while the current through the resistor 880 is controlled using the current mirror 860. The resistor 880 is connected at one end to the output node D and at its other end to the terminal E, which also connects to the second path 864 of the current mirror 860. The inductive load 210 is connected to a first path 862 of the current mirror 860, which is in series with the load branch, and which controls the current flowing in the second path 864 of the current mirror 860. The first path 862 is formed by a pair of transistors 870, 872. The drain terminal and gate terminal of the transistor 870 are both connected to the inductive load 210. The drain terminal and gate terminal of the transistor 872 are both connected to the source terminal of the transistor 870. The source terminal of the transistor 872 is connected to the reference potential. The second path 864 is formed by a pair of transistors 874, 876. The drain terminal of the transistor 874 connects to the resistor 880 at node E. The gate terminal of the transistor 874 is connected to the inductive load 210 and thus the gate of the transistor 870. The drain terminal of the transistor 876 is connected to the source terminal of the transistor 874. The gate terminal of the transistor 876 is connected to the source terminal of the transistor 870 and thus to the gate of the transistor 872. The source terminal of the transistor 876 is connected to the reference potential. In one example implementation, the transistors 870, 872, 874 and 876 are n-type transistors. Additionally, or alternatively, the transistors 870, 872, 874 and 876 may all have the same parameters (e.g. the same channel length and/or same channel thickness) so that their behavior is identical.

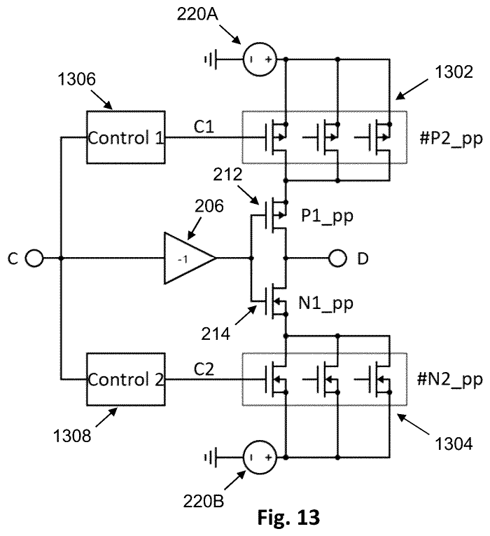

Although shown as single transistors, each of the transistors 870, 872, 874 and 876 may be realized by multiple transistors connected in parallel, similar to the case in FIG. 13 explained below (see transistors 702 and 704). Thus, by suitably configuring the amount of current that can be conducted in the first path 862 and second path 864 of the current mirror 860 (e.g. by selecting appropriate numbers of parallel transistors in each path and/or the parameters of the transistors in each path), the current mirrored from the first path 862 into the second path 864 can be substantially lower than that in the first path 862. For higher energy efficiency of the amplifier design, the mirrored current signal in the second path 864 of the current mirror 860 (through transistors 874, 876) should be many times (e.g. N-times) smaller than the output current flowing through the load 210 and the first path 862 of the current mirror 860. To compensate for this mirror ratio 1/N for the control loop, the resistance R_{convert} of the resistor 880 may be equal to the product of the resistance R_{load} of the line resistance 210B of the inductive load 210 and N (i.e. the inverse of the mirror ratio 1/N).

The exemplary voltage divider 216 is formed from two resistors 216 (Rdiv1) and 230 (Rdiv2) and the center tap of the voltage divider in between the two resistors 216, 230 is connected to the inverting terminal B of the comparator 204 thereby completing the control loop. The voltage divider 216 could also be implemented using two capacitances. The ratio of the resistances of the resistors 216 and 230 can be set, controlled or designed to achieve the desired amplification gain of the amplifier circuit 800, 800′.

As noted, the impedance of the feedback branch 850 may be very high so that the power flowing into the feedback stage 850 is minimized. This allows for very high energy efficiency of the amplifier 800, 800′. Notably, the line resistance R_{load} of the load 210 and the transistors 870, 872 of the first path 862 of the current mirror 860 form another voltage divider. This additional voltage divider limits the maximum current through the load branch, and also requires a higher output voltage at node D compared to exemplary implementations where the inductive load 210 is connected to the reference potential directly, in order to compensate for the additional voltage drop at the transistors 870, 872 of the first path 862. It should also be noted that the charging and discharging constant of the load inductance 210A (L_{load}) over time is influenced by the current mirror 860 as well.

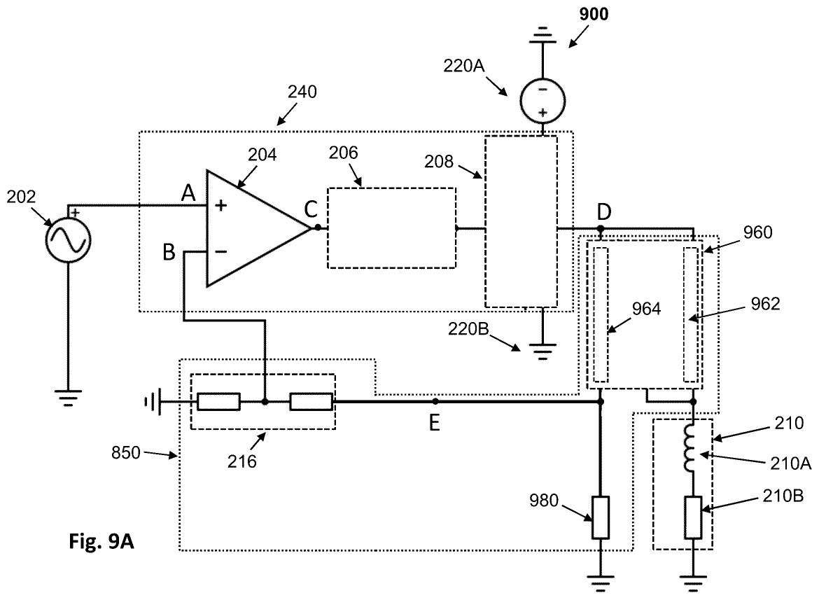

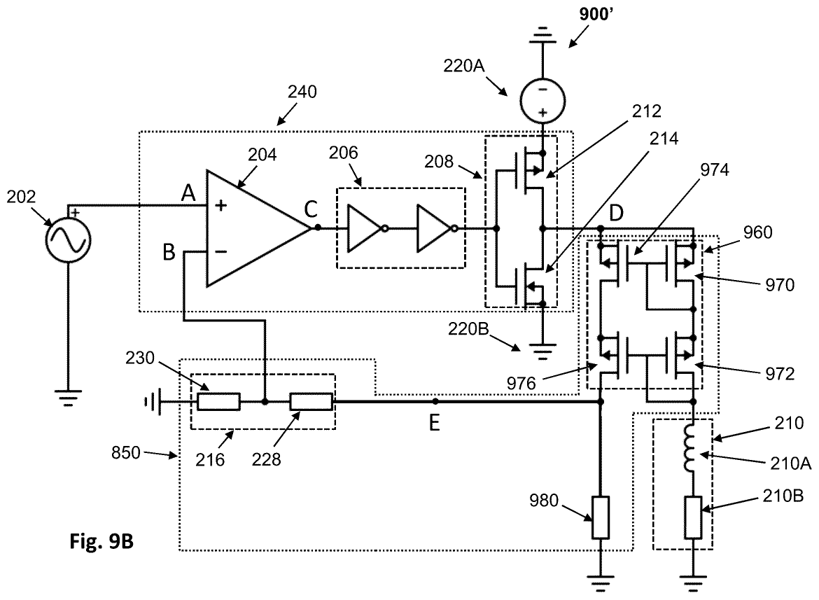

FIG. 9A shows a schematic circuit implementation realizing a tracking amplifier 900 according to another embodiment of the invention. The amplifier circuit 900 comprises an amplification stage 240 and a feedback stage 850, similar to the example of FIG. 8A. In the example embodiment of FIG. 9A, the feedback stage 850 comprises a current mirror 960, a resistor 980 and a voltage divider 216. Different from the embodiment in FIG. 8A, the current mirror 960 is connected between the output node D on one side, and the resistor 980 and the inductive load 210 at the other side. The current mirror 960 mirrors the load current flowing from/into the node D through the inductive load 210 and the first path 962 of the current mirror 960 to the second path 964 of the current mirror 960. Hence, a mirrored time-continuous current signal in the second path 964 is proportional to the load current flowing from the node D through the first path 962 of the current mirror 960. Due to the impedance of the voltage divider 216 being substantially higher than that of the second path 964 of the current mirror 960, the current flowing through the resistor 980 will thus be substantially the same as the mirrored current signal in the second path 964 of the current mirror 960. The input terminal of the resistor 980, which connects to the node E, provides a time-continuous voltage to the voltage divider 216 which is (substantially) equivalent to the mirrored time-continuous current signal through the resistor 980. The other terminal of the transistor 980 is connected to the reference potential. The resistor 980 thus converts the mirrored time-continuous current signal to flow into node D or from the node D into the amplifier circuit 800 into a time-continuous voltage signal. The mirrored time-continuous voltage signal from the resistor 980 is provided at the node E and is applied to the voltage divider 216. The voltage divider 216 adjusts the mirrored time-continuous voltage signal that is provided at node E to an appropriate voltage level for application to the inverting terminal B of the comparator 204.

FIG. 9B shows a schematic circuit diagram of a tracking amplifier 900′ according to another example embodiment. The amplifier circuit 900′ may be considered a more detailed implementation of the amplifier circuit 800 shown in FIG. 9A. In the example implementation, the amplification stage 240 of the amplifier circuit 900′ may be identical to the amplification stage 240 of the amplifier circuit 800′ discussed in in connection with FIG. 8B above. As noted in connection with FIG. 9A above, the current mirror 960 of the feedback stage 850 is connected in between the output node D, and to the resistor 980 and inductive load 210. Resistor 980 is used to convert a time-continuous mirrored current signal that is proportional to the time-continuous current signal that flows through the inductive load 210 (impedance L_{load} and line resistance R_{load}) into a time-continuous voltage. The current signal through the resistor 980 is thereby controlled by the current mirror 960. The resistor 980 is connected at one end to the node E and at its other end to the reference voltage. The terminal of the resistor 980 connected to node E also connects to the second path 964 of the current mirror 960. The inductive load 210 is connected to a first path 962 of the current mirror 960, which is in series with the load branch, and which controls the current flowing in the second path 964 of the current mirror 960. The first path 962 of the current mirror 960 is formed by a pair of transistors 970, 972. The source terminal of the transistor 970 is connected to the node D. The drain terminal of the transistor 970 is connected to the gate terminal of the transistor 970 and the source terminal of the transistor 972. The drain terminal of the transistor 972 is connected to the gate terminal of the transistor 972 and the inductive load 210. The second path 964 is formed by a pair of transistors 974, 976. The source terminal of the transistor 974 connects to the output node D of the amplifier 900′. The gate terminal of the transistor 974 is connected to the gate of the transistor 970 (and thus also to its drain terminal). The source terminal of the transistor 976 is connected to the drain terminal of the transistor 974. The gate terminal of the transistor 976 is connected to the gate terminal of the transistor 972 (and thus also to its drain terminal). The drain terminal of the transistor 976 is connected to the resistor 980 at the node E. In one example implementation, the transistors 970, 972, 974 and 976 are p-type transistors. Additionally, or alternatively, the transistors 970, 972, 974 and 976 may all have the same parameters (e.g. the same channel length and/or same channel thickness) so that their behavior is identical.

Although shown as single transistors, each of the transistors 970, 972, 974 and 976 may be realized by multiple transistors connected in parallel, similar to the case in FIG. 13 explained below (see transistors 702 and 704). Thus, by suitably configuring the amount of current that can be conducted in the first path 962 and second path 964 of the current mirror 960 (e.g. by selecting appropriate numbers of parallel transistors in each path and/or the parameters of the transistors in each path), the current mirrored from the first path 962 into the second path 964 can be substantially lower than that in the first path 962. For higher energy efficiency of the amplifier design, the mirrored current signal in the second path 964 of the current mirror 960 (through transistors 974, 976) should be many times (e.g. N-times) smaller than the output current flowing through the load 210 and the first path 962 of the current mirror 960. To compensate for this mirror ratio 1/N for the control loop, the resistance R_{convert} of the resistor 980 may be equal to the product of the resistance R_{load} of the line resistance 210B of the inductive load 210 and N (i.e. the inverse of the mirror ratio 1/N).

The exemplary voltage divider 216 is formed from two resistors 216 (Rdiv1) and 230 (Rdiv2) and the center tap of the voltage divider in between the two resistors 216, 230 is connected to the inverting terminal B of the comparator 204 thereby completing the control loop. The voltage divider 216 could also be implemented using two capacitances. The ratio of the resistances of the resistors 216 and 230 can be set, controlled or designed to achieve the desired amplification gain of the amplifier circuit 900, 900′.

As noted, the impedance of the feedback branch 850 may be very high so that the power flowing into the feedback stage 850 is minimized. This allows for very high energy efficiency of the amplifier 900, 900′. Notably, the line resistance R_{load} of the load 210 and the transistors 970, 972 of the first path 962 of the current mirror 960 form another voltage divider. This additional voltage divider limits the maximum current through the load branch, and also requires a higher output voltage at node D compared to exemplary implementations where the inductive load 210 is connected to the reference potential directly, in order to compensate for the additional voltage drop at the transistors 970, 972 of the first path 962. It should also be noted that the charging and discharging constant of the load inductance 210A (L_{load}) over time is influenced by the current mirror 960 as well.

In both example embodiments shown in FIGS. 8B and 9B, the discharge of the output current at terminal D can be through the inductive load. Hence, in an alternative implementation, it is possible to replace the inverter stage 208 by a transistor (e.g. transistor 212 only, and “cancelling” the transistor 214, or vice versa), which has its drain terminal connected to the output terminal D.

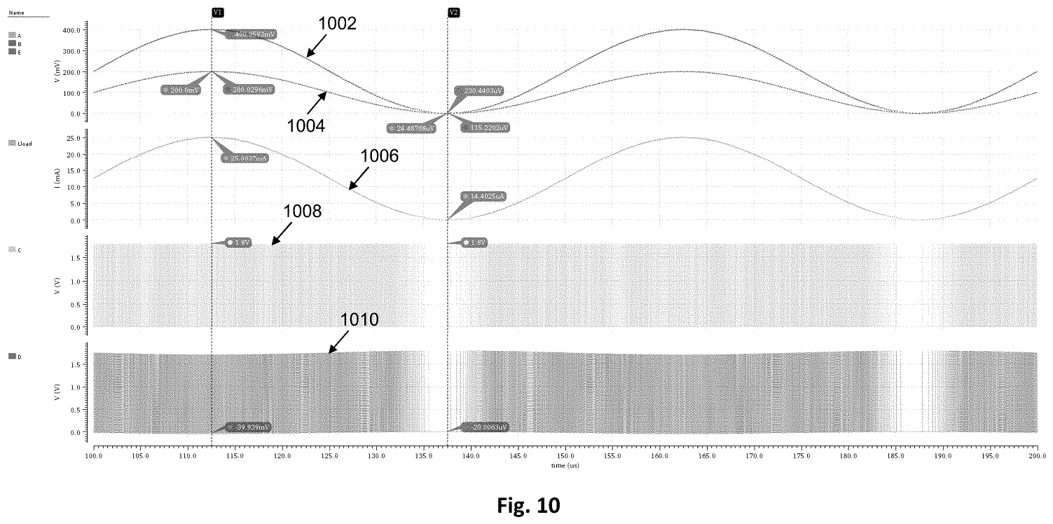

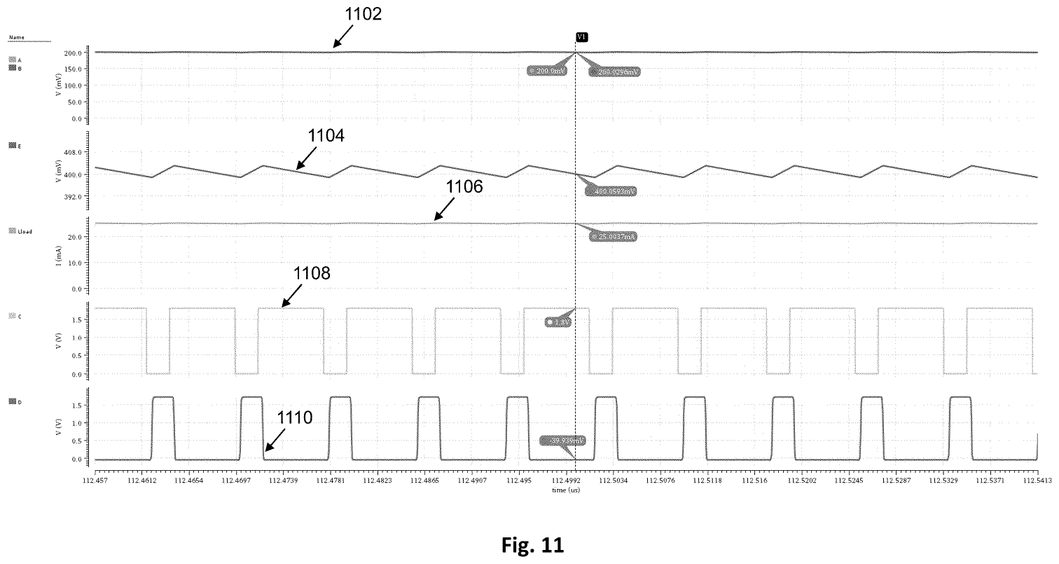

FIGS. 10 and 11 show example waveforms 1002, 1004, 1006, 1008 and 1010 in any one of the amplifier circuits 300, 500, 700, 750, 800′, 900′ as shown in FIGS. 3, 5, 7A, 7B, 8B and 9B. FIG. 11 zooms into signal waveforms of FIG. 10 around the marker V1 to the left in FIG. 10. The input signal 202, 1002 in the shown example is a 20 kHz sine wave at the input terminal A with a DC offset of 100 mV and an amplitude of 100 mV. The amplification factor is set to 2 by the voltage divider 216, so the maximum voltage at E must be twice as high as at input terminal B of the comparator 204, at 400 mV. The signal waveform at node E is denoted with the reference numeral 2021002 in FIGS. 10 and 1104 in FIG. 11. The pulse sequence at output node D is shown by reference numeral 1010 in FIG. 10 and reference numeral 1110 in FIG. 11.

In the embodiments in FIGS. 2 and 3, the pulse sequence at node D is integrated in the load inductance 210A of the load 210 thereby producing the time-continuous target current (see reference numeral 1006 in FIG. 10 and reference numeral 1106 in FIG. 11) and in the low-pass filter 224, 226 for generating the feedback voltage at node E.

In the embodiments in FIGS. 4 and 5, the pulse sequence at node D is integrated in the load inductance 210A of the load 210 thereby producing the time-continuous target current (see reference numeral 1006 in FIG. 10 and reference numeral 1106 in FIG. 11) and in the feedback network 422 for generating the feedback voltage at node E.

In the embodiments in FIGS. 6, 7A and 7B, the pulse sequence at node D is integrated in the load inductance 210A of the load 210 thereby producing the time-continuous target current (see reference numeral 1006 in FIG. 10 and reference numeral 1106 in FIG. 11) and the resistor 626 generates the corresponding feedback voltage at node E.

In the embodiments in FIGS. 2 to 6, 7A and 7B, the line resistance R_{load} of the load inductance 210B of 16Ω paired with a voltage of 400 mV at node E gives the desired maximum output current at node D of 25 mA at the same time as the input-side voltage signal 202 at node A reaches its maximum (the output current at node D is denoted with the reference numeral 1006 in FIG. 10 and reference numeral 1106 in FIG. 11). Reference numerals 1008 and 1108 denote the PWM voltage signal produced by the comparator 204 at its output node C, which alternates between 0.0 V and 1.8 V in the example shown.

In the embodiments in FIGS. 8A, 8B, 9A and 9B, the pulse sequence at node D is integrated in the load inductance 210A of the load 210 thereby producing the time-continuous target current (see reference numeral 1006 in FIG. 10 and reference numeral 1106 in FIG. 11). This time-continuous current is mirrored at a given ratio by the current mirror 860 thereby producing a corresponding mirrored current flowing through the resistor 880. This mirrored current signal is converted by the resistor 880 into a time-continuous voltage signal provided at the feedback voltage at node E. In this example, the resistor 880 produces a voltage of 400 mV at node E gives the desired maximum output current at node D of 25 mA at the same time as the input-side voltage signal 202 at node A reaches its maximum (the output current at node D is denoted with the reference numeral 1006 in FIG. 10 and reference numeral 1106 in FIG. 11). Reference numerals 1008 and 1108 denote the PWM voltage signal produced by the comparator 204 at its output node C, which alternates between 0.0 V and 1.8 V in the example shown.

In contrast to a capacitive load as shown in FIG. 1, the discharge current may flow via the load inductance. Hence, the (n-type) transistor 214 is optional, i.e. the inverter stage 208 may alternatively be implemented using the (p-type) transistor 212 only, as noted above.

To further improve the tracking capabilities of the amplifier circuit it would be advantageous to provide improved control of the current sourced towards or sinked from the load 210. Due to the “on-off” nature of the push-pull stage 208 of the switching amplifiers in FIGS. 2 to 6, 7A, 7B, 8A, 8B, 9A and 9C, the induced ripple at the output node D could be reduced for small signal amplitudes by reducing the current driven by the push-pull output transistors 212, 214. This procedure may be adjustable depending on the desired output signal amplitudes.

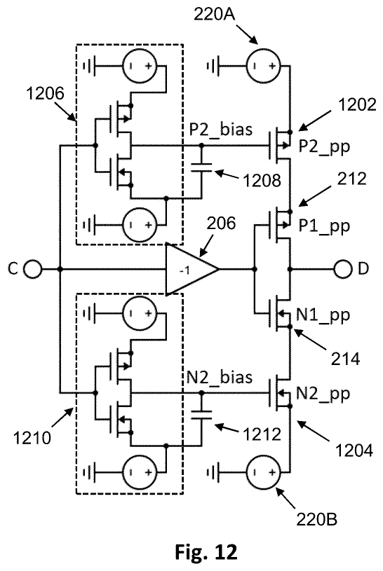

FIGS. 12, 13 and 14 show further exemplary modifications of the output stage of the amplifiers in FIGS. 2 to 6, 7A, 7B, 8A, 8B, 9A and 9C according to different embodiments of the invention that allow for a dynamic driving strength for the overall amplifier design.

FIG. 12 shows the first modification of the output stage for use in amplifiers of FIGS. 2 to 6, 7A, 7B, 8A, 8B, 9A and 9C. The push-pull transistor 212 is connected to the reference potential 220A via a bias transistor 1202 that control the current flowing through the push-pull transistor 212 to the output terminal D of the inverter stage 208. The source of the transistor 212 is connected to the drain of the transistor 1202. The source of transistor 1202 is connected to the reference potential 220A. Transistors 212 and 1202 may be for example p-type transistors. Similarly, the push-pull transistor 214 is connected to a second reference potential 220B via another bias transistor 1204 that controls the current flowing through the push-pull transistor 214 to the output terminal D of the inverter stage 208. The source of the transistor 214 is connected to the drain of the transistor 1204. The source of transistor 1204 is connected to the second reference potential 220B, which may be for example GND. Transistors 214 and 1204 may be for example n-type transistors. Transistors 212 and 214 act as switches and are driven by the output signal of the comparator 204 at node C which is passed through a buffer 206, which is implemented by an inverter.

The control signal from node C is also forwarded to two integrator circuits. Each of the integrator circuits are formed by an inverter 1206, 1210 and a buffer capacitor 1208, 1212 to create the bias signals P2_bias and N2_bias applied to the gate terminals of the bias transistors 1202 and 1204. The bias signals are analog (and not digital signals) causing the transistors 1202 and 1204 to act as voltage dependent resistors that limit the current that can be sourced towards or sinked from the output node D. The key idea for this simple implementation of a dynamic driving strength is the utilization of the comparator output signal provided at node C for turning on and off and further for increasing or decreasing the corresponding bias signals and therefore output currents.

If the potential at node C is logically high the potential on output D should be increased. At the same time the bias signal P2_bias will decrease depending on the corresponding time constant and therefore lower the effective resistance of p-type transistor 1202 which increase the current that can be sourced. If the potential at node C is logically low, the potential at the output node D should decrease. At the same time the bias signal N2_bias will increase depending on the corresponding time constant and therefore lower the effective resistance of n-type transistor 1204 which increase the current that can be sinked.

Because the signal at node C is pulse-width modulated, the bias signals will change accordingly to the resulting pulse widths. Therefore, the driving strength of the output stage is also controlled by the comparator 204 which is linked to the feedback loop at output node D.

FIG. 13 shows the second modification of the output stage for use in one of the amplifiers in FIGS. 2 to 6, 7A, 7B, 8A, 8B, 9A and 9C, which is somewhat similar to the first modification described in connection with FIG. 12. The push-pull transistor 212 is connected to the reference potential 220A via a plurality of bias transistors 1302 connected in parallel that control the current flowing through the push-pull transistor 212 to the output terminal D of the inverter stage 208. The source of the transistor 212 is connected to the drain terminals of the transistors 1302. The source terminals of transistors 1302 are connected to the reference potential 220A. Transistors 212 and 1302 may be for example p-type transistors. Similarly, the push-pull transistor 214 is connected to a second reference potential 220B via another a plurality of bias transistors 1304 connected in parallel that control the current flowing through the push-pull transistor 214 to the output terminal D of the inverter stage 208. The source of the transistor 214 is connected to the drain terminals of the transistors 1304. The source terminals of transistors 1304 are connected to the second reference potential 220B, which may be for example GND. Transistors 214 and 1304 may be for example n-type transistors. Transistors 212 and 214 act as switches and are driven by the output signal of the comparator 204 at node C which is passed through a buffer 206, which is implemented by an inverter.

In FIG. 13 the PWM signal at node C is further processed in a bias control circuit 1306 and bias control circuit 1308. Those circuit blocks 1306 and 1308 may be for example realized in digital logic, e.g. a counter or a switch matrix implementing a functionality to selectively enable or disable a certain number of parallel bias transistors 1302 and 1304 using the control signals C1 and C2, respectively. Dependent on the number of enabled/disabled transistors 1302, 1304, the resistance of the bias transistors 1302, 1304 connected in parallel can be varied, so that the bias transistors 1302, 1304 behave like the bias transistors 1202, 1204 in FIG. 12. In contrast, to FIG. 12, each of the bias transistors 1302, 1304 behaves like a switch that is either activated or deactivated (switched on and off) dependent on the control signals applied to the respective gate terminals of the bias transistors 1302, 1304. The transistors 1302, 1304 may not be all have the same gate-width and/or gate-length and that the control logic 1306, 1308 does not have to switch the bias transistors 1302 or 1304 sequentially one by one. It is also possible that the number of activated “switches” 1302 or 1304 is selected in a binary/exponential manner depending on the processing of the output signal of the comparator 204 at the node C.

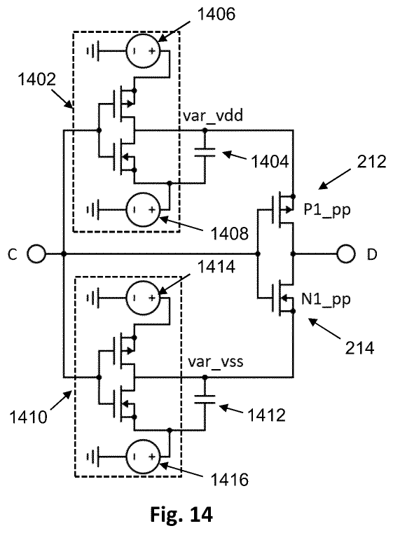

FIG. 14 shows the third modification of the output stage for use in in one of the amplifiers in FIGS. 2 to 6, 7A, 7B, 8A, 8B, 9A and 9C. Different from FIGS. 12 and 13, the modification in FIG. 14 does not use additional bias transistors in addition to the push-pull transistors 212, 214. Instead, two integrator circuits similar to those shown in FIG. 12 used to provide an upper variable supply rail (at node var_vdd) and a lower variable supply rail (var_vss) for the output transistors 212 and 214. Like in FIG. 12, the integrator circuit providing the upper variable supply rail (at node var_vdd) is formed by an inverter circuit 1402 that connected to two reference potentials 1406 and 1408 in between which the upper variable supply rail at node var_vdd can vary. The output current of the inverter 1402 charges the buffer capacitor 1404 to provide the variable upper supply rail voltage at the node var_vdd to the source terminal of the push-pull transistor 212. Similarly, the integrator circuit providing the lower variable supply rail at node var_vss is formed by an inverter circuit 1410 that connected to two reference potentials 1414 and 1416 in between which the lower variable supply rail at node var_vss can vary. The reference potential 1414 may be higher than the reference potential 1416. Reference potential 1416 may be the lowest potential among reference potentials 1406, 1408, 1414 and 1416, whereas reference potential 1406 may be the highest potential. The output current of the inverter 1410 charges the buffer capacitor 1412 to provide the variable lower supply rail voltage at node var_vss to the source terminal of the push-pull transistor 214.

If the potential at node C is logically high, the potential on output node D should be decreased. If the potential at node C is high the p-type push-pull transistor 212 is disabled and the n-type push-pull transistor 214 is enabled, so that only the potential difference between the output terminal D and the lower supply rail at node var_vss is of relevance. With the high potential at node C, the energy stored in the capacitor 1412 can be discharged towards the lowest reference potential 1416 which decreases the potential at node var_vss. This causes the potential difference between output node D and the node var_vss to change, which is equivalent to a change in the output resistance to sink current from node D like described before. This current will flow from output node D over the capacitance 1412 at node var_vss and through the NFET of the inverter 1410 towards the reference potential 1416. Dependent on the on-resistance of the inverter 1410's NFET, the on-resistance of the push-pull transistor 214 and the charges stored on the capacitor 1412, a resulting current from output node D will flow and change over time.

If the potential at node C is logically low, the potential at output node D should be increased. If the potential at node C is low, the n-type push-pull transistor 214 is disabled and the p-type push-pull transistor 212 is enabled, so that the potential difference between the output node D and the upper supply rail at node var_vdd is relevant. With the low potential at node C the energy stored in the capacitor 1404 at node var_vdd can be charged towards the highest reference potential 1406 which increases the potential at node var_vdd. This causes the potential difference between output node D and the node var_vdd to change, which is equivalent to a change in the output resistance to source current towards output node D like described before. This current will flow from the PFET of the inverter 1402 over the capacitance 1404 at node var_vdd and through the push-pull transistor 212 towards the output node D. Dependent on the on-resistance of this PFET of the inverter 1402, the on-resistance of the push-pull transistor 212 and the already stored charges at the capacitor 1404, a resulting current will flow towards the output node D and will change over time.

Notably, the influence of the potential at node C on the current flow in FIG. 14 is exactly the opposite compared to FIGS. 12 and 13. Because a digital signal is provided as a PWM pulse train at node C, the logic behind it can be inverted anytime in the signal chain. Also, the inputs to the comparator 204's terminals A and B could be exchanged to invert the PWM-signal at node C. When using a fully differential comparator having outputs B and B̅, where the signal at output B̅ is the negated/180°-phase shifted version of the signal at output B, the signal at output B̅ could be used to provide the signal at node C.

In the claims:

1-96. (canceled)

97. An amplifier circuit for coupling to an inductive load, the amplifier circuit comprising:
an amplification stage comprising:
a comparator, wherein the comparator has a non-inverting input terminal and an inverting input terminal which are configured to receive a signal to be amplified and a feedback signal and to produce and output at its output terminal a comparator output signal by comparing the signal to be amplified and the feedback signal; and
an inverter stage configured to generate a pulse-width modulated signal in response to the comparator output signal and to output the pulse-width modulated signal as a time-continuous current signal at an output terminal of the inverter stage, the output terminal of the inverter stage being also the output terminal of the amplifier circuit;
a feedback stage, wherein the feedback stage comprises:
a feedback filter that is to be coupled in parallel to the inductive load and that is coupled directly to the output terminal of the inverter stage to receive and convert the time-continuous current signal into a time-continuous voltage signal; and
a voltage divider receiving the time-continuous voltage signal at its input and coupled to a reference potential at its output, wherein the voltage divider is configured to provide the time-continuous voltage signal at a reduced voltage level as the feedback signal to the comparator.

98. The amplifier circuit of claim 97, wherein the signal to be amplified is received at non-inverting input terminal of the comparator and the feedback signal is received at the inverting input terminal of the comparator.

99. The amplifier circuit of claim 97, wherein the feedback filter is a low-pass filter.

100. The amplifier circuit of claim 98, wherein the impedance of the feedback filter is higher than the impedance of the inductive load to minimize the power flowing into the feedback filter.

101. The amplifier circuit of claim 97, wherein the voltage divider comprises a first resistor and a second resistor coupled in series,
wherein the first resistor has one terminal coupled to an output of the feedback filter to receive a time-continuous voltage signal and another terminal coupled to the one of the input terminals of the comparator to provide the feedback signal; and
wherein the second resistor has one terminal coupled to the other terminal of the first resistor and another terminal coupled to the reference potential.

102. The amplifier circuit of claim 97, wherein the voltage divider comprises a first capacitor and a second capacitor coupled in series,
wherein the first capacitor has one terminal coupled to an output of the feedback filter to receive a time-continuous voltage signal and another terminal coupled to the one of the input terminals of the comparator to provide the feedback signal; and
wherein the second capacitor has one terminal coupled to the other terminal of the first capacitor and another terminal coupled to the reference potential.

103. The amplifier circuit of claim 97, wherein the signal to be amplified has a voltage level relative to the reference potential.

104. The amplifier circuit of claim 97, wherein the amplification stage further comprises one or more buffer circuits which are connected in series between the output terminal of the comparator and an input terminal of the inverter stage.

105. The amplifier circuit of claim 104, wherein the one or more buffer circuits are configured to perform level shifting of the comparator output signal and to provide the level shifted comparator output signal to the input terminal of the inverter stage,
wherein the one or more buffer circuits are configured to amplify the drive strength of the signal applied to the input terminal of the inverter stage.

106. The amplifier circuit of claim 97, wherein the inverter stage comprises at least one pair of push-pull transistors connected in series and forming a push-pull configuration.

107. The amplifier circuit of claim 106, wherein a first push-pull transistor of the pair of push-pull transistors is a p-type transistor and the other second push-pull transistor of the pair of push-pull transistors is a n-type transistor.

108. The amplifier circuit according to claim 106, wherein a first push-pull transistor of the pair of push-pull transistors is connected to a first reference potential and another second push-pull transistor of the pair of push-pull transistors is connected to a second reference potential, which is different from the first reference potential.

109. The amplifier circuit according to claim 106, wherein a first push-pull transistor of the pair of push-pull transistors is connected to a first reference potential via one or more first bias transistors configured to control the current flowing through the first push-pull transistor to the output terminal of the inverter stage, and
wherein another second push-pull transistor of the pair of push-pull transistors is connected to a second reference potential via another one or more second bias transistors configured to control the current flowing through the second push-pull transistor to the output terminal of the inverter stage,
wherein the one or more first bias transistors and the one or more second bias transistors form variable resistances.

110. The amplifier circuit according to claim 109, further comprising:
a first bias control circuit configured to apply a bias signal to the gate terminal(s) of the one or more first bias transistors in response to the comparator output signal to thereby control the current flowing through the first push-pull transistor to the output terminal of the inverter stage; and
a second bias control circuit configured to apply a bias signal to the gate terminal(s) of the one or more second bias transistors in response to the comparator output signal to thereby control the current flowing through the second push-pull transistor to the output terminal of the inverter stage.

111. The amplifier circuit according to claim 110, wherein the first and second bias control circuits are configured to integrate the comparator output signal and to provide the integrated comparator output signal as the bias signal to the gate terminals of the one or more first and second bias transistors, respectively.

112. The amplifier circuit according to claim 110, wherein the first bias control circuit is configured to selectively activate and deactivate a selected number of the first bias transistors in response to the comparator output signal to thereby control the current flowing through the first push-pull transistor to the output terminal of the inverter stage; and
the second bias control circuit is configured to selectively activate and deactivate a selected number of the second bias transistors in response to the comparator output signal to thereby control the current flowing through the first push-pull transistor to the output terminal of the inverter stage, preferably wherein the first and second bias control circuits implement a counter or a switch matrix to selectively activate or deactivate the selected number of bias transistors.

113. The amplifier circuit according to claim 111, wherein each of the first and second bias control circuits comprise an inverter circuit connected between two DC voltage reference and a buffer capacitor connected between the output of the inverter circuit and one of the DC voltage references.

114. The amplifier circuit of claim 97, wherein the inverter stage comprises multiple cascaded inverters.

115. An amplifier circuit for coupling to an inductive load, the amplifier circuit comprising:
an amplification stage comprising:
a comparator, wherein the comparator has a non-inverting input terminal and an inverting input terminal which are configured to receive a signal to be amplified and a feedback signal and to produce and output at its output terminal a comparator output signal by comparing the signal to be amplified and the feedback signal; and
an inverter stage configured to generate a pulse-width modulated signal in response to the comparator output signal and to output the pulse-width modulated signal as a time-continuous current signal at an output terminal of the inverter stage, the output terminal of the inverter stage being also the output terminal of the amplifier circuit;
a feedback stage, wherein the feedback stage comprises:
a resistor coupled in series with the inductive load, wherein the resistor is to convert the time-continuous current signal flowing through the inductive load into a time-continuous voltage signal;
a voltage divider receiving the time-continuous voltage signal at its input and coupled to a reference potential at its output, wherein the voltage divider is configured to provide the time-continuous voltage signal at a reduced voltage level as the feedback signal to the comparator.

116. An amplifier circuit for coupling to an inductive load, the amplifier circuit comprising:
an amplification stage comprising:
a comparator, wherein the comparator has a non-inverting input terminal and an inverting input terminal which are configured to receive a signal to be amplified and a feedback signal and to produce and output at its output terminal a comparator output signal by comparing the signal to be amplified and the feedback signal; and
an inverter stage configured to generate a pulse-width modulated signal in response to the comparator output signal and to output the pulse-width modulated signal as a time-continuous current signal at an output terminal of the inverter stage that is to flow through the inductive load, the output terminal of the inverter stage being also the output terminal of the amplifier circuit;
a feedback stage, wherein the feedback stage comprises:
a current mirror having a first path through which the time-continuous current signal is to flow and a second path, wherein current mirror is configured to cause a mirrored time-continuous current signal to flow through the second path of the current mirror, the mirrored time-continuous current signal corresponding to the time-continuous current signal flowing through the first path;
a resistor having one terminal connected to the second path of the current mirror, and another terminal connected either to the output terminal of the amplifier circuit or a reference potential, wherein the resistor is configured to convert the mirrored time-continuous current signal flowing through the second path of the current mirror into a time-continuous voltage signal; and
a voltage divider receiving the time-continuous voltage signal at its input and coupled to the reference potential at its output, wherein the voltage divider is configured to provide the time-continuous voltage signal at a reduced voltage level as the feedback signal to the comparator.
